(19) United States
(12) Patent Application Publication
(10) Pub. No.: US 2026/0128251 A1
(43) Pub. Date: May 7, 2026

(54) PREVENTING ESD IN PRT SEM DISCHARGES

(71) Applicant: Carl Zeiss SMT GmbH, Oberkochen (DE)

(72) Inventors: Hans Hermann Pieper, Schaafheim (DE); Daniel Alexander Emmrich, Darmstadt (DE); Lalitha Kodumudi Venkataraman, Plankstadt (DE); Claudia Kroeckel, Egelsbach (DE); Katharina Bitsch, Lindenfels (DE); Rene Kullock, Darmstadt (DE)

(21) Appl. No.: 19/427,057

(22) Filed: Dec. 19, 2025

Related U.S. Application Data
(63) Continuation of application No. PCT/EP2024/067474, filed on Jun. 21, 2024.

(30) Foreign Application Priority Data
Jun. 22, 2023 (DE) 102023205886.3

(51) Int. Cl. H01J 37/02; H01J 37/28

(52) U.S. Cl. CPC H01J 37/026; H01J 37/28; H01J 2237/0473; H01J 2237/2577

(57) ABSTRACT

The present invention relates, inter alia, to a method for influencing a charge state of a sample, comprising directing a charged particle beam onto the sample for the purpose of analyzing and/or processing the sample, wherein the particles of the particle beam are accelerated onto the sample by a first acceleration voltage and result in charging of the sample, and directing the charged particle beam onto the sample for the purpose of influencing the charging of the sample, wherein the particles of the particle beam are accelerated onto the sample by a second, changed acceleration voltage amounting to at least 15% of the first acceleration voltage.

### CROSS-REFERENCE TO RELATED APPLICATIONS

This application is a continuation of and claims benefit under 35 U.S.C. § 120 from PCT Application No. PCT/EP2024/067474, filed on Jun. 21, 2024, which claims priority from German Application No. 10 2023 205 886.3, entitled “Verhindern von ESD in PRT SEM Entladungen,” filed on Jun. 22, 2023. The entire contents of each of these earlier applications are incorporated herein by reference.

### TECHNICAL FIELD

The present invention relates to methods, a computer program and a device for influencing a charge state of a sample.

### BACKGROUND

Analyzing and/or processing a lithographic mask (also referred to herein as mask) by use of a particle beam has been known for a relatively long time. For example, the particle beam may comprise an electron beam, ion beam and/or a photon beam which is provided in a defined manner on the mask for the purpose of analyzing and/or processing the mask. Providing the particles of the particle beam on the mask allows various interactions to be generated, which can enable various analysis processes and/or processing processes of the mask. In this regard, particle beam-based analyzing and/or processing of a mask may comprise a wide variety of methods.

For example, the particle beam-based processing may comprise a particle beam-induced etching and/or deposition, within the scope of which material of a mask is removed or generated locally. For example, this may comprise an electron beam-induced etching and/or deposition. Furthermore, a defined photon irradiation of the mask may also be required, e.g., for processing the mask (e.g., in the case of a laser-induced reaction). Examining a mask using a particle beam may, for example, comprise an image of the mask being recorded with the aid of the particles in the particle beam (e.g., as occurs with the aid of an electron beam in the case of a scanning electron microscope (SEM)).

Particle beam-based analyzing and/or processing of a mask using a particle beam is now used for various applications in industry. In other applications, it may also be necessary to remove foreign bodies from the surface of a mask, at least partly on the basis of using a tip of a scanning probe microscope.

For example, in the semiconductor industry, increasingly smaller structures are produced on a wafer in order to ensure an increase in integration density. Among the methods used here for the production of the structures are lithography methods which image these structures onto the wafer. The lithography methods may include, for example, photolithography, ultraviolet (UV) lithography, DUV lithography (i.e., lithography in the deep ultraviolet spectral region), EUV lithography (i.e., lithography in the extreme ultraviolet spectral region), x-ray lithography, nanoimprint lithography, etc. Masks are usually used here as lithography objects (e.g., photomasks, exposure masks, reticles, stamps in the case of nanoimprint lithography, etc.), which comprise a pattern in order to image the desired structures onto a wafer, for example.

As the integration density increases, so do the demands in respect of the mask production (e.g., as a result of the accompanying reduction in the structure dimensions on the mask or as a result of the greater material requirements in lithography). Thus, mask production processes are becoming ever more complex, time-consuming and expensive. It is not always possible to avoid mask errors (e.g., defects). Thus, the mask errors are usually repaired by way of particle beam-based processing since they can only be repaired, e.g., in particle beam-based fashion on account of their small dimensions.

Furthermore, it may be necessary to examine masks using a particle beam, for example, in the semiconductor industry. For example, the repair of mask errors may thus require image recordings of the mask errors or the repair location to be effected using a particle beam (e.g., for a high-resolution SEM image).

Other industrial purposes may also require a sample to be analyzed and/or processed using a particle beam. For example, this may be carried out for the analysis (e.g., a defect analysis) of a sample which may comprise, e.g., a microchip, a wafer, a biological sample, etc. In some cases, an analysis of a sample may also comprise an AFM image recording of the sample. Processing the sample may comprise, e.g., removing a particle (e.g., a foreign particle) from the sample (e.g., in the context of a so-called particle pick process).

However, the masks to be analyzed and/or processed using the particle beam may have an (unwanted) electrostatic charging.

Disadvantageous effects may be caused by the (unwanted) electrostatic charging. For example, the (unwanted) electrostatic charging may result in the particle beam being deflected away from the intended point of incidence on the mask. Furthermore, the electrostatic charging may also result, e.g., in a particle beam-based reaction not achieving the desired effect. Thus, the (unwanted) electrostatic charging may impair the defined analyzing and/or processing of the mask in an undesired manner.

Thus, defined analyzing and/or processing of the mask using a particle beam usually requires a technical workaround for the effects caused by the electrostatic charging of the mask.

Some problem solutions for this purpose are already known from the prior art.

In some cases, a charging of the mask can be eliminated by an electrical contact being applied in the region of conductive structures of a mask which are surrounded by an electrical insulation. However, this entails the risk of the mask being damaged (scratched) or contaminated (generation of foreign particles) and may result in the processable region of the mask being restricted (installation space restriction owing to the contact). In the case of a plurality of structures on the mask which are not connected (e.g., are separated from one another by an insulation), these structures cannot be jointly earthed with a single electrical contact on the mask. Instead, e.g., a plurality of electrical contacts on the mask may be required in order to enable the relevant regions to be earthed.

In other cases, a charging may be influenced by at least local gassing of the mask. If a suitable gas is brought into the vicinity of a particle beam (e.g., an electron beam of a scanning electron microscope, SEM), the gas may neutralize charges on a surface of the mask. The gas that is supplied, however, in interaction with the particle beam of the SEM, may undesirably change the surface of the mask (e.g., at least local cleaning, oxidation, activation of the surface). Likewise, the gas that is supplied may affect possible repair processes carried out on the mask (e.g., etching steps, fixing foreign particles on an AFM tip). Furthermore, any required pumping away of the (neutralizing) gas that is supplied may reduce the throughput of a device that implements the neutralizing method. In some cases, it may also happen that the gas or its constituents may undesirably contribute to contamination of the mask.

A further possibility for counteracting a charging of a mask may be provided, e.g., by a flood gun. In this case, a flood gun irradiates the mask with an electron beam that is chosen with regard to beam voltage and beam current in such a way that it compensates for the charging by an SEM. What is disadvantageous in this case, however, is that the secondary electrons generated by a flood gun may likewise be detected by a detector of the SEM and, as a result, may generate an offset that may make an automated SEM image evaluation more difficult. Moreover, it may be necessary that the flood gun must be aligned with the SEM spot on the mask since otherwise, according to the dependence of the mask position and the mask structure, the charging by the SEM cannot be compensated for. This alignment often cannot be realized satisfactorily by devices used owing to installation space restrictions. A discharge step which is carried out subsequently and involves the mask position analyzed in the SEM being moved to the flood gun may greatly reduce the throughput of such a device.

In some cases, a charge present on the mask may also be at least partly dissipated by a plasma discharge. However, such discharges of a mask (e.g., as described in U.S. Pat. No.9,995,764 B2) may greatly reduce the throughput of a device that processes the mask. In addition, an attendant requirement for the switching of valves (e.g., when an SEM is used) and the attendant admission of gases may contaminate the mask.

In some cases, a charging of the mask may also be compensated for by a bias voltage applied to the AFM tip of a scanning probe microscope. Using AFM techniques, such as, e.g., Kelvin probe force microscopy (KPFM), e.g., a potential of the AFM tip can be matched to a potential of the mask, with voltages in the range of +/−10 V typically being used. However, an AFM tip, and the electronic and mechanical setup associated therewith, are not designed for a higher voltage, e.g., of the order of magnitude of a few kV (which may correspond to a charging of the mask), and so a corresponding bias voltage cannot be applied.

The already known solutions for influencing a charge state of a mask have a large number of disadvantages and enable a charge state of a mask to be influenced only unsatisfactorily.

Consequently, there is the need to improve the analyzing and/or examining of masks by use of a particle beam, and to provide possibilities for improved influencing of a charge state of a mask. In particular, there is a need to provide an improved concept for influencing a charge state of a mask which takes account of the large number of possible applications (e.g., in SEM and/or AFM microscopy) in which an unwanted charging of a mask results in disadvantageous analyzing and/or examining of a mask.

### SUMMARY

The abovementioned general aspect is at least partly achieved by the various aspects of the present invention, as described below.

A first aspect of the present invention relates to a method for influencing a charge state of a sample. The method may comprise directing a charged particle beam onto the sample for the purpose of analyzing and/or processing the sample, wherein the particles of the particle beam may be accelerated onto the sample by a first acceleration voltage and result in charging of the sample. Furthermore, the method may comprise directing the charged particle beam onto the sample for the purpose of influencing the charging of the sample, wherein the particles of the particle beam are accelerated onto the sample by a second, changed acceleration voltage amounting to at least 15% of the first acceleration voltage.

Selecting the second acceleration voltage in such a way that the latter amounts to at least 15% of the first acceleration voltage may allow efficient influencing of the charge contained on the sample to be achieved. The applicant has recognized that decreasing the first acceleration voltage to a second acceleration voltage which is small in comparison with the first acceleration voltage and which amounts to significantly less than at least 15% of the first acceleration voltage may result, e.g., in repulsion of incident particles of the particle beam if the charging of the sample results in a repulsive opposing field for the particles of the particle beam. This may be explained by the fact that a kinetic energy of the particles of the particle beam may be decreased by an interaction with the repulsive opposing field, with the result that said particles can no longer reach the sample. The applicant has recognized that this disadvantageous effect may be at least partly overcome if, rather than the second acceleration voltage being selected directly to be small in comparison with the first acceleration voltage, said second acceleration voltage should correspond to at least 15% of the first acceleration voltage. What may be achieved in this way is that the particles of the particle beam that are accelerated by the second acceleration voltage, as they approach the charged sample, still have enough kinetic energy to be able to overcome an electrostatic potential which, e.g., has a repulsive effect on the incident particle beam and may reduce a landing energy of the incident particles. Furthermore, what may be achieved by selecting the second acceleration voltage is that particles of the particle beam which were accelerated by use of the second acceleration voltage are incident on the sample with lower landing energy (in comparison with particles of the particle beam which were accelerated by the first acceleration voltage). The attendant reduced landing energy of the particles may result in an increase in a secondary electron yield and in this way contribute to influencing of the charge present on the sample. Efficient and rapid influencing of a charge present on a sample may be provided in this way.

The particle beam may be provided by a scanning electron microscope.

In some applications, the sample may be provided, e.g., as a lithographic mask.

In some cases, the second, changed acceleration voltage may be less than the first acceleration voltage. The second, changed acceleration voltage here may be less than the first acceleration voltage, e.g., in terms of absolute value.

The analyzing may comprise recording x-ray beams generated in the sample by the particle beam.

Generation of a (continuous) bremsspectrum (and thus of x-ray beams) in the sample may be achieved by implementing the particle beam as an electron beam. The (initially continuous) bremsspectrum obtained may additionally contain element-specific peaks (characteristic of the elements contained in the sample and/or of, e.g., particles (foreign particles) on the sample). These element-specific peaks may be initiated, e.g., by the excitation of electron transitions in the elements contained in the sample and/or of, e.g., particles (foreign particles) on the sample. This excitation may be effected, e.g., by raising (e.g., by use of a (resonant) portion of the bremsstrahlung) electrons on an electron shell close to an atomic nucleus (of the element) to an electron shell situated further away from the atomic nucleus. This may be followed by a de-excitation of the atom, wherein a transition of the raised electron to an electron shell situated closer to the atomic nucleus may take place. That may be accompanied by the emission of an element-specific radiation, which may be manifested as element-specific peaks (as described above). For example, energy-dispersive x-ray spectroscopy (EDX) may be made possible in this way.

An element analysis of elements present in the sample may be made possible by the recording. This may advantageously contribute to analyzing possible foreign bodies present on the sample and, if appropriate, their origin.

The first acceleration voltage may amount to at least 1 kV, more preferably at least 3 kV and most preferably at least 4 kV.

In some cases, the first acceleration voltage may also have higher voltage values, such as, e.g., at least 5 kV, 10 kV, 15 kV, 20 kV, 30 kV, 40 kV, 50 kV or an even higher voltage value.

In some (exemplary) cases, e.g., an EDX recording with a first acceleration voltage of 4 kV may be effected. In some (exemplary) cases, e.g., an imaging by use of a scanning electron microscope, SEM, with a first acceleration voltage of 2-3 kV may be effected.

In some cases, the sample may be charged up to a potential corresponding to the first acceleration voltage.

Targeted setting of the first acceleration voltage may enable an adaptation of the maximum frequency (according to the Duane-Hunt law) of the generated bremsspectrum for an envisaged application. By setting the first acceleration voltage to a value tending to be higher, e.g., the maximum frequency of the generated bremsspectrum may be shifted in the direction of higher frequencies of the bremsspectrum. This may furthermore also enable a targeted excitation of particles contained in the sample and/or of particles (e.g., foreign particles) on the sample. This in turn may result in the formation of corresponding (higher-energy) element-specific peaks in addition to the (continuous) bremsspectrum (as described above).

The second acceleration voltage may amount to at least 30%, preferably at least 40%, particularly preferably at least 50% and most preferably at least 60% of the first acceleration voltage.

A slow and controlled decrease of the second acceleration voltage may be achieved in this way. This may ensure that particles of the particle beam may reach the (charged) sample and may not be repelled by the repulsive potential possibly still present on the charged sample and may thus possibly not contribute to influencing the charge state of the sample.

The particle beam for the analyzing may comprise a particle current of at least 5 pA, preferably at least 1 nA and most preferably at least 150 nA.

In some alternative cases, it may be possible for the particle current to amount to less than 5 pA (e.g., 1 pA to 4 pA or an arbitrary intermediate value) or however also more than at least 150 nA, at least 200 nA or at least 500 nA. Particularly preferably, the particle current may be chosen, e.g., in such a way that it lies in the range of 10 pA to 100 nA.

The choice of the particle current makes it possible, for example, if the particles of the particle current are provided as electrons, to control the number of generated x-ray photons which arise when the particles of the particle beam are incident on the sample. This may, if e.g. a particle current tending to be higher is chosen (e.g., 1000 pA instead of, e.g., 10 pA), contribute to a higher number of generated x-ray photons and thus increase the counting rate when x-ray spectroscopy is carried out, which may reduce the time duration required for the x-ray spectroscopy in order to obtain desired counting statistics.

The particle current during the analyzing and/or processing of the sample may be substantially equal to the particle current during the influencing of the charging of the sample.

In this context, the term “substantially” may be understood such that, apart from (negligible) statistical fluctuations, the particle current may be constant during the analyzing and/or processing of the sample.

This may contribute to a simplified control of the influencing of the charging since there is no need for readjustment of the particle current upon transition from analyzing and/or processing the sample to influencing the charging of the sample.

Alternatively, a particle current which exceeds the particle current for analyzing and/or processing the sample may also be chosen in some cases for influencing the charging of the sample. This may contribute to more rapid and more efficient influencing of the charging of the sample in some cases. Alternatively, provision may also be made for a particle current during the analyzing of the sample to differ from a particle current for influencing the sample. In such a case, the particle current for influencing the charging of the sample may be chosen in such a way that it lies between the particle current for analyzing the sample and the particle current for processing the sample. This may enable continuous and more accurately targeted adaptation of operational parameters for an SEM recording.

The method may furthermore comprise directing the charged particle beam onto the sample N times for the purpose of influencing the charging of the sample, wherein the particles are accelerated onto the sample by a respectively N-th acceleration voltage, wherein N is greater than or equal to two.

Directing the charged particle beam may be understood to mean controlling (e.g., by use of at least one operational parameter selected accordingly) the charged particle beam in such a manner that makes it possible to direct the charged particle beam with (predefined) properties onto the sample (or a region of the sample).

In some cases, directing the charged particle beam N times may be configured in such a way that the charged particle beam is switched off and/or blocked between two successive iterations of the directing.

This may contribute to the fact that particles of the particle beam which are incident on the sample may ideally contribute to influencing the charge state of the sample and may not be repelled by the latter, by virtue of a repulsive opposing field possibly present, and not reach the sample.

In some cases, the N-th acceleration voltage may amount to at least 15% of the (N−1)-th acceleration voltage. In some cases, the N-th acceleration voltage may amount to at least 30%, preferably at least 40%, particularly preferably at least 50%, very particularly preferably at least 60% and most preferably at least 70% of the (N−1)-th acceleration voltage.

This may contribute to influencing the charge state of the sample as efficiently as possible.

The N-th acceleration voltage may be at least 250 V less than the (N−1)-th acceleration voltage and/or the N-th acceleration voltage may be at most 4 kV less than the (N−1)-th acceleration voltage.

However, reducing the N-th acceleration voltage vis-à-vis the (N−1)-th acceleration voltage is not restricted to these values. In some cases, it is also possible for the N-th acceleration voltage to be at least 200 V or at least 100 V less than the (N−1)-th acceleration voltage. In particular, the N-th acceleration voltage may be 250 V to 3 kV, more preferably 0.5 kV to 2 kV, less than the (N−1)-th acceleration voltage, in particular if the first acceleration voltage amounts to 10 kV. In some cases, the N-th acceleration voltage may also be 1 kV or 1.5 kV less than the (N−1)-th acceleration voltage.

This may likewise contribute to influencing the charge state of the sample as efficiently as possible.

The directing N times may take place successively, wherein reducing the acceleration voltage at least twice may be carried out.

In some cases, the acceleration voltage may also be reduced at least three times, four times, five times or, e.g., even ten times. This may contribute to influencing the charge state of the sample in a finely granular manner.

The reducing at least twice may take place by the same absolute value in each case.

This may contribute to simplified influencing of the charge state of the sample since there is no need to change the absolute value (e.g., in the sense of redetermining the absolute value) by which the acceleration voltage is reduced.

In some embodiments, the second acceleration voltage may be at least 4 kV, preferably at least 4.4 kV, most preferably at least 4.8 kV. In addition, or alternatively, the second acceleration voltage may be at most 6 kV, preferably at most 5.6 kV, most preferably at most 5.2 kV. In particular, the second acceleration voltage may be approximately 5 kV. Generally, the second acceleration voltage may be independent of the charge state of the sample, and may provide a suitable starting point for discharging the sample independent of its initial charge state. For example, the second acceleration voltage may also be independent of a difference between a potential of the sample and a potential of a device (e.g., an SPM and/or a cantilever of the device, as described below). It is noted that in some examples, e.g., the potential difference may be −2 kV after the analyzing and/or processing the sample. But for the methods described herein, measuring the potential difference is not always necessary. Generally, directing the charged particle beam with the second acceleration voltage onto the sample may comprise directing the charged particle beam with the second acceleration voltage onto the sample for a second period of time. In some examples, the second period of time may be at least 10 seconds, at least 30 seconds, or about 60 seconds. In some examples, the second period of time may be at most 300 seconds, at most 200 seconds, or at most 100 seconds.

In some examples, one or more further steps of directing the charged particle beam onto the sample for the purpose of influencing the charge state of the sample, wherein the particles of the particle beam are accelerated onto the sample by a respective acceleration voltage, may be carried out one after another for a respective period of time.

In some examples, the acceleration voltage may be reduced by about 500 V to 1.5 kV from one step to the subsequent step.

For example, four or five further steps may be applied. In some examples, four further steps are applied, wherein the period of time of the three initial ones or the four further steps is approximately equal to the second period of time and/or the period of the last one of the four further steps is approximately two times the second period of time, and wherein the voltage reductions in each step may optionally be approximately equal. In another example, five further steps are applied, wherein the periods of time for each step are approximately equal, and wherein the voltage reduction from the penultimate to the last step is optionally smaller than each of or at least one of the previous voltage reductions.

In addition, the method may further comprise directing the charged particle beam onto the sample for the purpose of influencing, wherein the particles of the particle beam are accelerated onto the sample by a third acceleration voltage. This step may be carried out subsequent to the directing with the second acceleration voltage. The third acceleration voltage may be smaller than the second acceleration voltage. For example, the third acceleration voltage may be smaller than 5 kV, preferably smaller than 4.6 kV, most preferably smaller than 4.2 kV. In addition, or alternatively, the third acceleration voltage may be at least 3 kV, preferably at least 3.4 kV, most preferably at least 3.8 kV. In some embodiments, the third acceleration voltage may be approximately 4 kV. Generally, directing the charged particle beam with the third acceleration voltage onto the sample may comprise directing the charged particle beam with the third acceleration voltage onto the sample for a third period of time which may be identical or similar to the second period of time.

In addition, the method may further comprise directing the charged particle beam onto the sample for the purpose of influencing, wherein the particles of the particle beam are accelerated onto the sample by a fourth acceleration voltage. This step may be carried out subsequent to the directing with the third acceleration voltage. The fourth acceleration voltage may be smaller than the third acceleration voltage. For example, the fourth acceleration voltage may be smaller than 4 kV, preferably smaller than 3.6 kV, most preferably smaller than 3.2 kV. In addition, or alternatively, the fourth acceleration voltage may be at least 2 kV, preferably at least 2.4 kV, most preferably at least 2.8 kV. In some embodiments, the fourth acceleration voltage may be approximately 3 kV. Generally, directing the charged particle beam with the fourth acceleration voltage onto the sample may comprise directing the charged particle beam with the fourth acceleration voltage onto the sample for a fourth period of time which may be identical or similar to the second period of time.

In addition, the method may further comprise directing the charged particle beam onto the sample for the purpose of influencing, wherein the particles of the particle beam are accelerated onto the sample by a fifth acceleration voltage. This step may be carried out subsequent to the directing with the fourth acceleration voltage. The fifth acceleration voltage may be smaller than the fourth acceleration voltage. For example, the fifth acceleration voltage may be smaller than 3 kV, preferably smaller than 2.6 kV, most preferably smaller than 2.2 kV. In addition, or alternatively, the fifth acceleration voltage may be at least 1 kV, preferably at least 1.4 kV, most preferably at least 1.8 kV. In some embodiments, the fifth acceleration voltage may be approximately 2 kV. Generally, directing the charged particle beam with the fifth acceleration voltage onto the sample may comprise directing the charged particle beam with the fifth acceleration voltage onto the sample for a fifth period of time which may be identical or similar to the second period of time.

In addition, the method may further comprise directing the charged particle beam onto the sample for the purpose of influencing, wherein the particles of the particle beam are accelerated onto the sample by a sixth acceleration voltage. This step may be carried out subsequent to the directing with the fifth acceleration voltage. The sixth acceleration voltage may be smaller than the fifth acceleration voltage. For example, the sixth acceleration voltage may be smaller than 2 kV, preferably smaller than 1.6 kV, most preferably smaller than 1.2 kV. In addition, or alternatively, the sixth acceleration voltage may be at least 0.3 kV, preferably at least 0.6 kV, most preferably at least 0.9 kV. In some embodiments, the sixth acceleration voltage may be approximately 1 kV. Generally, directing the charged particle beam with the sixth acceleration voltage onto the sample may comprise directing the charged particle beam with the sixth acceleration voltage onto the sample for a sixth period of time.

In general, the second period may be essentially the same as the third period and/or the fourth period and/or fifth period. For example, the second, third, fourth, and fifth period of time may be mutually essentially the same. The sixth period of time may be longer than the first and/or second and/or third and/or fourth and/or fifth period of time. For example, the sixth period may be about 150% to 250% of the second, third, fourth, and/or fifth period. For example, it may be approximately twice as long as the second, third, fourth, and/or fifth period.

In addition, or alternatively, the method may further comprise directing the charged particle beam onto the sample for the purpose of influencing, wherein the particles of the particle beam are accelerated onto the sample by a seventh acceleration voltage. This step may be carried out subsequent to the directing with the sixth acceleration voltage. The seventh acceleration voltage may be smaller than the sixth acceleration voltage. For example, the seventh acceleration voltage may be smaller than 1 kV, preferably smaller than 0.8 kV, most preferably smaller than 0.6 kV. In addition, or alternatively, the seventh acceleration voltage may be at least 0.1 kV, preferably at least 0.2 kV, most preferably at least 0.3 kV. In some embodiments, the seventh acceleration voltage may be approximately 0.5 kV. Generally, directing the charged particle beam with the seventh acceleration voltage onto the sample may comprise directing the charged particle beam with the seventh acceleration voltage onto the sample for a seventh period of time.

In some embodiments, the step of directing the charged particle beam onto the sample for the purpose of influencing, wherein the particles of the particle beam are accelerated onto the sample by a seventh acceleration voltage may (only) be performed if the sixth period of time is essentially the same as the fifth period of time. Also the seventh period of time may be essentially the same as the fifth period of time.

Directing the charged particle beam onto the sample according to the above-described scheme, e.g., using a second, third, fourth, fifth, sixth and optionally seventh acceleration voltage may allow to efficiently influence the charge contained on the sample. In particular, the charge contained on the sample may be influenced such that after directing the charged particle beam accelerated according to the sixth and/or sevens acceleration voltage, a voltage of the sample may be at most 40 V, preferably at most 30 V, most preferably at most 20 V. The voltage of the sample may comprise a difference between the potential of the sample and the potential of at least a part of a device as described herein, e.g., a tip and/or a cantilever of the device. The tip and/or cantilever may be an SPM tip and/or an SPM cantilever of an SPM of the device. The device may additionally or alternatively comprise a particle beam source, e.g., as part of an SEM of the device. In other words, the device may be a combined SPM and SEM device. Preferably, after the process, the potential on the sample may be lower than a potential allowed by a tool for measuring the charge state of the sample, e.g., a tool for detecting at least one sample parameter as described herein. In other words, the process may reliably bring the sample into a state which is accessible for the tool, such that the charge state and/or further sample parameters may be safely determined.

It is presently assumed that this workflow reliably brings the sample to the mentioned low charge state and/or potential difference, as the second acceleration voltage may be seen as a ramp to a predefined (negative) charge state, and the ramping down by the steps outlined above may reproducibly discharge the sample to the low charge state and/or potential difference.

In some examples, one or more further steps of directing the charged particle beam onto the sample for the purpose of influencing, wherein the particles of the particle beam are accelerated onto the sample by a respective acceleration voltage, may be carried out one after another (after the first and second steps), wherein the voltage drops in from second to third, third to fourth, etc., steps may be smaller than described above. For example, the voltage may be reduced by about 0.1 kV to 1 kV in each step, until a final voltage in the range of 0.3 kV to 1.3 kV is reached. In that case, shorter periods of time may be used compared to the periods of time outlined above. For example, if only a voltage drop of 0.1 kV is used between subsequent steps, for example, the respective steps could be applied for about 0.1 seconds to 30 seconds, for example about 0.5 seconds to 10 seconds, or about 1 second.

In other examples, the voltage may be reduced continuously or approximately continuously, e.g., with an average gradient of about 1 V/s to 1 kV/s, for example, about 10V/s to 50 V/s, or approximately to an average gradient comparable to that of a step-wise reduction as outlined above.

It is noted that the value of about 5 kV outlined herein for the second acceleration voltage is just exemplary. In other examples, particularly also higher values may be used, such as, e.g., up to 10 kV or more. In those cases, it is understood that similar voltage drop step sizes as outlined above, e.g., in the range of 0.1 kV to 1 kV or 0.5 kV to 1.5 kV (and more specific values as outlined herein), may be used until a final acceleration voltage of about 0.1 kV to 1.3 kV, or 0.3 to 1.1 kV is reached. Particularly, gradients as outlined above may be used also in this case, for example, in combination with a continuous or approximately continuous reduction.

Generally, the voltage of the sample may be (further) reduced by measuring the charge state of the sample. Measuring the charge state of the sample may be made possible, e.g., by detecting at least one process parameter (as described herein) and generally by measuring a potential of the sample. Measuring the charge state of the sample may in some examples only be possible if the voltage of the mask is below 400 V, preferably below 300 V, most preferably below 200 V. Hence, it may be particularly preferable to implement the ramping down outlined above to reliably reduce the voltage of the sample below 40 V, preferably below 30 V, most preferably below 20 V. Then, the charge state of the sample may be measured and/or quantified also by sensitive methods. Depending on the measured charged state and/or the measured voltage of the sample, a further charged particle beam may be directed onto the sample according to an eight's acceleration voltage, wherein the eights acceleration voltage depends on the measured charged state and/or the measured voltage of the sample. For example, if the charge state of the sample is negative, the eight's acceleration voltage may be at most 2 kV, preferably at most 1.6 kV, most preferably at most 1.2 kV and/or at least 0.2 kV, preferably at least 0.5 kV, most preferably at least 0.8 kV. If the charge state of the sample is positive, the eight's acceleration voltage may be at most 7 kV, preferably at most 6 kV, most preferably at most 5.5 kV and/or at least 3 kV, preferably at least 4 kV, most preferably at least 4.5 kV. Generally, directing the charged particle beam with the eight's acceleration voltage onto the sample may comprise directing the charged particle beam with the eight's acceleration voltage onto the sample for an eight's period of time. The duration of the eight's period of time may depend on the charge state of the sample. In particular, the duration may depend on an absolute value of the charge state of the sample. For example, for a smaller absolute value of the charge state of the sample a shorter duration may be sufficient.

In general, after directing the charged particle beam onto the sample according to the eight's acceleration voltage, the charge state of the sample may again be measured and/or quantified. This invites for an iterative process of directing the charged particle beam onto the sample according to an acceleration voltage (which may depend on the charge state measured by the previous measurement) and measuring the charge state of the sample. Generally, this iterative process may end if the charge state of the sample is in the range of −1 V to 1 V.

In some examples, the reducing at least twice may take place in such a way that the reduction absolute values follow a logarithmic profile.

The reduction absolute values may be arranged in such a way that they increase logarithmically with a number of reductions carried out (progressive profile). In this case, the respective reduction absolute values would become greater and greater as the number of reductions carried out increases. Alternatively, provision may also be made for the reduction absolute values to decrease logarithmically with the number of reductions carried out (degressive profile). In this case, the respective reduction absolute values would become smaller and smaller as the number of reductions carried out increases.

By providing the reduction absolute values such that they follow a logarithmic profile, e.g., in the case of a progressive profile firstly for an initial charge state of the sample just a low degree of influencing of the charge state may be carried out (in order, e.g., firstly to influence the charge state only slightly and to avoid repulsion reactions of the particles of the particle beam), which is superseded in the profile by larger reduction absolute values of the acceleration voltage (if e.g. there was a departure from a critical range for repulsion reactions) in order thus to attain more rapid influencing of the charge state of the sample.

Alternatively, it is also possible for the reducing at least twice to take place in such a way that the reduction absolute values are chosen so as to fall exponentially (with each of the at least two reduction steps).

Alternatively, the reducing of the acceleration voltage at least twice may also follow a continuous profile (for example, the reduction absolute values, in the case of, e.g., more than two reductions of the acceleration voltage, may be effected by the same absolute value).

The particle beam may be directed onto the sample without interruption between at least two acceleration voltages.

This means that the particle beam may be directed onto the sample continuously between at least two acceleration voltages. In some cases, the particle beam may also be directed onto the sample N times, with the result that the particle beam is directed onto the sample continuously. As a result of setting an acceleration voltage N times, however, the particle beam may experience a new particle beam configuration in each of the N iterations.

This may contribute to influencing the charge state of the sample more time-efficiently since the particle beam may be operated continuously and no time is needed for switching the particle beam on and off (and possibly ramping the operating parameters thereof).

The influencing may comprise reducing the charging of the sample.

In some cases, the sample may have at least one region (such as, e.g., in the case of chrome on glass blanks) which is not connected to an earth potential and which may experience a charging.

Consequently, the method steps described above make it possible to at least partly reduce a charging of a sample and prevent possibly occurring repulsive interactions between particles of the particle current and the charged sample.

The method may furthermore comprise detecting at least one process parameter associated with a present charge state of the sample.

The at least one process parameter may be associated with the particles of the particle beam and/or secondary particles caused by an interaction between the particles of the particle beam and the sample. Additionally or alternatively, the at least one process parameter may be associated with x-ray beams generated in the sample.

Detecting the at least one process parameter may enable a present charge state of the sample to be determined.

The second acceleration voltage may be at least partly based on the at least one process parameter. This may make it possible for the second acceleration voltage to be effected at least partly on the basis of a present charge state of the sample. In this regard, for example, in cases in which the sample is strongly charged, the second acceleration voltage may be reduced relative to the first acceleration voltage by a smaller percentage than in cases in which the sample is rather weakly charged. Consequently, a purposeful and situationally coordinated adaptation of the second acceleration voltage to a present charge state of the sample may be made possible.

The detecting may furthermore comprise modulating the acceleration voltage and demodulating the at least one process parameter.

The combination of modulating the acceleration voltage and demodulating the at least one process parameter may provide a lock-in detection method. Modulating the acceleration voltage may take place, e.g., periodically (e.g., by way of a modulation which follows a sine wave with a predetermined frequency in the time profile). Demodulating the at least one process parameter may take place, e.g., with the frequency with which the acceleration voltage was modulated.

Efficient suppression of noise that may affect a time profile of the at least one process parameter may be made possible in this way. This may contribute to an increased signal-to-noise ratio (SNR) of the at least one process parameter detected.

The method may furthermore comprise directing the particle beam onto the sample by use of an acceleration voltage which is at least partly based on a closed feedback loop including the at least one process parameter as input variable.

Tracking of the acceleration voltage may be made possible in this way, with the result that the acceleration voltage may react to changes (e.g., to a temporal drift) in the at least one process parameter as input variable efficiently (in comparison with manual adjustment of the acceleration voltage that might be necessary).

The at least one process parameter may be kept substantially constant in a time profile.

In this context, “substantially” may be understood such that the at least one process parameter is constant in a specific time interval and any fluctuation of the at least one process parameter that might be present is merely attributable to statistical fluctuations (e.g., as a result of noise). In this case, noise may refer both to electronic noise and to effects which are caused by a statistical fluctuation of process parameters associated with the particle beam (e.g., a fluctuating luminosity of the particle beam, a fluctuating acceleration voltage, etc.).

This makes it possible to ensure that the method may be operated in such a way that optimized influencing of the charge state of the sample in the time profile may be ensured.

The at least one process parameter may be associated with a secondary electron yield, SEY. In some cases, the at least one process parameter may be able to be derived from a current value based on detectable secondary electrons.

What may be achieved in this way is that an SEY (if the particles of the particle beam are provided as electrons) may be kept substantially constant in the time profile by way of the feedback loop mentioned above. Preferably, the SEY may be kept substantially constant in the time profile in such a way that it has a value of greater than 1. Preferably, the SEY may be chosen in such a way that a maximum value of the SEY is kept substantially constant.

This may make it possible for more than one electron to leave the charged sample per incident electron of the particle beam on average over time. This may therefore contribute in an efficient manner to optimized influencing of the sample (e.g., reducing the charging of the sample).

Recording an SEM image may occur upstream and/or downstream of the method.

In some cases, the recording of an SEM image, the method described herein and the downstream recording of an SEM image may be executed cyclically. This may contribute to an optimized workflow.

If the SEM image occurs downstream of the method, then influencing of the charge state of the sample may be provided by the method, with the result that unwanted effects caused by a charge state of the sample may be suppressed. If the sample is, e.g., negatively charged and the particles of the particle beam are provided as electrons, then an unwanted deflection (caused by a repulsive interaction of the charging present on the sample) of the electrons of the particle beam may be suppressed in this way.

The method may furthermore comprise providing an electrically conductive element. Furthermore, the method may comprise at least partly directing the charged particle beam onto the electrically conductive element in order to eject secondary particles from the electrically conductive element.

In some cases, the electrically conductive element may be fabricated completely from an electrically conductive material. In some cases, the electrically conductive element may be at least partly coated with an electrically conductive material. The electrically conductive material may comprise, e.g., a doped semiconductor and/or a metal.

In some exemplary applications, the electrically conductive element may also be provided as a shielding element (e.g., as a net), which may be mounted above a sample, as is known, e.g., from EP 1 587 128 (as shielding element).

In some cases, the electrically conductive material may comprise a scanning probe microscope, SPM, tip and/or a cantilever of an SPM. In some cases, the particle beam may be directed both onto the sample and onto the electrically conductive element (e.g., simultaneously). The electrically conductive element may be connected to an earth potential. The electrically conductive element may be provided in such a way that it is situated at a distance of, e.g., 0.5 mm-2 mm, preferably approximately 1 mm, from a surface of the sample. In some cases, however, provision may also be made for the distance between the electrically conductive element and the surface of the sample to be chosen to be (significantly) less than 0.5 mm.

This may contribute to improved influencing of a charge state of a sample. If e.g. a sample is discharged (e.g., for the purpose of discharging a negative charging of the sample), then in some cases it may happen that the negatively charged sample adopts a positive charging as a result of the discharging process and thus result once again in a now opposite (e.g., positive) charging of the sample. This may be at least partly prevented by the particle beam being directed not only onto the sample itself but additionally also at least partly onto an SPM tip connected (to an earth potential), and/or an SPM cantilever. From the SPM tip and/or the cantilever of the SPM, secondary electrons may then be ejected, for example, which may be accelerated towards the positively charged sample and may advantageously contribute there to a neutralization of the charging.

A second aspect of the present invention relates to a method for influencing a charge state of a sample. The method may comprise providing a scanning probe microscope, SPM, tip and producing an electrically conductive connection between the sample and the SPM tip for the purpose of influencing the charge state. In this way, by use of an SPM tip used, e.g., for removing foreign particles present on the sample, influencing of the charge state of the sample may additionally be made possible as well, whereby additional, separate devices for influencing the charge state of the sample may become dispensable. This may contribute to influencing the sample in a cost-effective manner. Furthermore, for the purpose of influencing the charge state of the sample, it is not necessary to switch between a plurality of devices (which might be provided for influencing the sample), rather it is only necessary to have recourse to the SPM tip already used for removing foreign particles. This may contribute to more time-efficient influencing of the charge state of the sample.

In some cases, the SPM tip may be provided as a tip of an atomic force microscope, AFM.

The method may comprise directing a particle beam onto the sample for the purpose of analyzing and/or processing the sample. Producing the electrically conductive connection may be at least partly based on a measured and/or expected charge state of the sample.

The analyzing and/or processing of the sample may be provided as described above.

Measuring the charge state of the sample may be made possible, e.g., by detecting at least one process parameter (as described herein). An expected transition may be, e.g., at least partly based on at least one predetermined calibration function (e.g., comprising an assignment of a (first) acceleration voltage and a duration of the analyzing and/or processing of the sample to a resultant charge state of the sample). The calibration function may be provided, e.g., as a look-up table which assigns, e.g., a (first) acceleration voltage, a duration of the analyzing and/or processing of the sample to a resultant expected (or previously measured) charge state of the sample.

In this way, targeted production of the electrically conductive connection of AFM tip and sample may be initiated if a charge state of the sample is expected which may have a disadvantageous effect on subsequent analyzing and/or processing of the sample. A proactive build-up of a charging of the sample may thus be suppressed.

The method may take place in a combined scanning probe microscope-scanning electron microscope device.

In some cases, the method may be executed without the sample situated in the device having to be removed.

This may furthermore efficiently enable an imaging of the sample (by use of the scanning electron microscope), e.g., in order to find foreign particles potentially present on the sample, which may be determined in more specific detail, e.g., by way of an x-ray examination (as described herein). If it transpires in the further course of the procedure that it is necessary to remove the foreign particle, then this may be made possible by use of the combined scanning probe microscope-scanning electron microscope device. Firstly, this may enable optimized handling of foreign particles possibly present on the sample and, secondly, by using the AFM tip of the scanning probe microscope, an unwanted charging of the sample may be suppressed or, if already present, dissipated in order to suppress, e.g., disadvantageous effects on the imaging by use of the scanning electron microscope that are caused by a charge state of the sample.

Producing the electrically conductive connection may take place by bringing the SPM tip closer to a surface of the sample.

The producing may thus relate to bringing the SPM tip closer to a surface of the sample in such a way that no electrically conductive connection between the SPM tip and the surface of the sample is present before the bringing closer and it is not until as a result of ending the bringing closer that an electrically conductive connection between the SPM tip and the surface of the sample is produced.

In this way, if a charging of the sample is already present, more accurate detecting of a present charge state of the sample may be made possible with each step of bringing the SPM tip closer towards the sample.

The bringing closer may take place step by step.

The bringing closer may be made possible, e.g., by moving the AFM tip by use of a stepper motor and/or a piezo-based actuator. The step size may be, e.g., 10 μm, 20 μm, 30 μm, 40 μm, 50 μm, 60 μm, 70 μm, 80 μm, 90 μm or 100 μm. Alternatively, provision may be made for the step size to be more than 100 μm or less than 10 μm. It is also possible for the step size to be chosen in such a way that it lies between those mentioned above.

In some cases, determining the charge state of the sample may take place after each step of the AFM tip towards the sample.

An approach by way of bringing closer step by step may prevent unwanted discharging of the sample that may result in damage to the AFM tip and/or the sample.

The bringing closer may take place continuously.

Bringing closer continuously may differ from bringing closer step by step in that the bringing closer does not have an explicitly provided residence point (e.g., for a predetermined temporal interval) at individual steps. In the case of bringing closer continuously, any residence possibly present may be attributable to characteristics of the drive (e.g., of a stepper motor used).

In some cases, producing the electrically conductive connection may take place by contacting the sample by way of the AFM tip.

Continuously bringing the AFM tip closer towards the sample may contribute to more rapid influencing of a charge state of the sample. This may be achieved by virtue of the fact that both measuring the charge state of the sample and possibly simultaneously directing a charged particle beam onto the sample already take place as early as during the bringing closer. Alternate bringing closer and directing may be dispensable. In this way, by use of the parallel bringing closer and directing, it is possible to contribute to more rapid influencing of a charge state of the sample.

The bringing closer may take place at least partly on the basis of detecting at least one process parameter.

The at least one process parameter may be associated with an interaction between the AFM tip and the sample. The at least one process parameter may be associated, e.g., with a (measured) force (attractive or repulsive) between the AFM tip and the sample, with a deflection (e.g., bending) of a cantilever of a scanning probe microscope and/or parameters derived therefrom.

The interaction may be based, e.g., on an attractive interaction between AFM tip and sample. In some cases, the AFM tip may be uncharged (neutral) at the beginning of the method. By bringing the AFM tip closer towards the sample, if the sample already has a charging, for example, a charge state which is opposite to the charge state of the sample may be induced in the AFM tip. This may contribute to an attractive interaction between the AFM tip and the sample.

In some cases, the bringing closer may be initiated by detecting an interaction actually present (e.g., an attractive or repulsive interaction) between the AFM tip and the sample. Detecting the interaction may be regarded as an indicator of an at least partial charging of the sample, which are stopped and influenced (e.g., dissipated) by the process of bringing the AFM tip closer towards the sample and subsequently producing an electrically conductive connection. Consequently, unwanted discharges of the sample may already be prevented at an early stage.

In some cases, bringing the AFM tip closer towards the sample any further may be terminated if the detected interaction gives an indication that the sample already has a charge state (e.g., a comparatively high charging) which would promote an unwanted discharge (e.g., by way of a flashover) of the sample via the AFM tip. The risk of damage to the sample and/or the AFM tip may thus be suppressed.

A third aspect of the present invention relates to a method for monitoring a charge state of a sample. The method may comprise detecting a process parameter associated with the charge state of the sample, and wherein the process parameter was recorded by one out of a scanning electron microscope, SEM, a scanning probe microscope, SPM, and/or an x-ray detector. Furthermore, the method may comprise determining the charge state of the sample at least partly on the basis of the process parameter.

The monitoring may be implemented in such a way that it detects the charge state of the sample continuously, i.e., without significant temporal interruptions, at least partly on the basis of the process parameter.

In this way, a rapid reaction to the charge state, if necessary, may be initiated and a further charging, if unwanted, may be prevented. Additionally or alternatively, if a charge state of the sample exceeds a predetermined threshold value, measures for influencing (e.g., for dissipating) the charge may be initiated. In this way, possible disadvantageous effects caused by the charge state may be prevented at an early stage and the throughput of a device that implements the method may be increased.

The determining may take place at least partly by way of a previously known relationship of the process parameter and the charge state of the sample.

The previously known relationship may be at least partly based on a calibration function and/or a look-up table, as described above.

The determining may be at least partly based on detecting an interaction between a tip of the SPM and the sample.

Detecting the interaction may be implemented as described above.

The method may furthermore comprise initiating a method (as described herein) for influencing the charge state of the sample if a predetermined charge threshold value of the sample is exceeded.

In this way, influencing the charge state of the sample may be initiated at an early stage, before e.g. there is a resulting risk of a discharge of the sample owing to a flashover from the sample to an AFM tip. This may prevent possible damage to the sample and/or the AFM tip.

The functions described above may be implemented in hardware, processor-executed software (e.g., as a computer program), firmware or any desired combination thereof. If they are implemented in software executed by a processor, the functions may be stored on a computer-readable medium as one or more instructions or codes or be transmitted by way thereof. The functions described here may be implemented, for example, with the aid of software executed by a processor, hardware, firmware, hard-wiring or combinations thereof. Features which implement functions may also be arranged physically at different positions, including a distribution, such that portions of the functions are implemented at different physical locations.

A fourth aspect of the present invention relates to a device for influencing a charge state of a sample. The device may comprise an electrically conductive element, such as, e.g., a scanning probe microscope, SPM, tip (and/or any other electrically conductive element described herein) and/or a particle beam of a scanning electron microscope, SEM (e.g., a corresponding source), and/or an x-ray detector. The device may furthermore comprise means for automatically executing one of the methods mentioned above.

In this way, an imaging of the sample (e.g., by use of the SEM) and/or processing of the sample (e.g., by removing a foreign particle from the sample by use of the AFM tip) may also be made possible besides influencing of the charge state of the sample.

The device may furthermore comprise means for controlling a distance between the SPM tip and the sample and/or an acceleration voltage of the particle beam.

The means for controlling may comprise, e.g., an (electric) motor, preferably a stepper motor. Additionally or alternatively, the means for controlling may comprise a piezoactuator and/or a piezo-based stepping drive (e.g., for step sizes >10 μm).

The device may furthermore contain means for executing the abovementioned computer program.

The means may comprise computer-readable media and/or at least one processor. The computer-readable media include both computer storage media and communication media including all media which facilitate the transmission of a computer program from one location to the other. A processor may be responsible for the management of the bus and the general processing, including the execution of software modules stored on the machine-readable storage medium. A computer-readable storage medium may be coupled to a processor, such that the processor may read and write information from and to the storage medium. Alternatively, the storage medium may also be integrated in the processor. By way of example, the machine-readable medium may comprise a transmission line, a carrier wave modulated with data and/or a computer-readable storage medium with instructions stored thereon separately from the wireless node, which may all be accessed by the processor via the bus interface. Alternatively or additionally, the machine-readable storage medium or a part thereof may be integrated in the processor, as may be the case for cache and/or general register files. Examples of machine-readable storage media are for example RAM (Random Access Memory), flash memory, ROM (Read Only Memory), PROM (Programmable Read-Only Memory), EPROM (Erasable Programmable Read-Only Memory), EEPROM (Electrically Erasable Programmable Read-Only Memory), registers, magnetic disks, optical disks, hard disks or any other suitable storage medium or any combination thereof. The machine-readable medium may be embodied in a computer program product.

A fifth aspect of the present invention relates to a method for influencing a charge state of a sample. The method may comprise directing a charged particle beam onto the sample for the purpose of analyzing and/or processing the sample, wherein the particles of the particle beam may be accelerated onto the sample by a first acceleration voltage and result in charging of the sample. Furthermore, the method may comprise directing the charged particle beam onto the sample for the purpose of influencing the charging of the sample, wherein the particles of the particle beam are accelerated onto the sample by a second acceleration voltage, wherein the second acceleration voltage is determined in such a way that a secondary particle yield caused by the second acceleration voltage is maximized.

Selecting the second acceleration voltage such that a secondary electron yield is maximized makes it possible to maximize the effect of influencing the charge state of the sample.

In some preferred cases, the particles may be provided as electrons.

The second acceleration voltage may be determined at least partly on the basis of a modulation of the first acceleration voltage and a demodulation of a process parameter associated with the charge state of the sample.

This may comprise a lock-in method, as already described above.

An at least third acceleration voltage may be selected in such a way (e.g., by use of a feedback loop) that the at least one process parameter is substantially kept constant in a time profile.

### BRIEF DESCRIPTION OF DRAWINGS

The following detailed description describes possible embodiments of the invention, with reference being made to the following figures:

FIG. 1 shows an exemplary curve profile of a secondary electron yield vs. a landing energy of electrons on a sample;

FIG. 2 shows an exemplary time profile of influencing a charge state of a sample in accordance with one aspect of the present invention;

FIG. 3 shows an exemplary SEY curve, wherein a landing energy of electrons experiences a modulation;

FIG. 4 shows an exemplary flow diagram in accordance with one aspect of the present invention;

FIG. 5 shows an exemplary flow diagram in accordance with one aspect of the present invention;

FIG. 6 shows an exemplary flow diagram in accordance with one aspect of the present invention;

FIG. 7 shows an exemplary flow diagram in accordance with one aspect of the present invention;

FIG. 8 illustrates one exemplary implementation of a charge monitor.

### DETAILED DESCRIPTION

Embodiments of methods according to the invention and of devices according to the invention are described in detail below. It should be pointed out, however, that the use of devices according to the invention and of the methods according to the invention is not restricted to the examples discussed below. Rather, these can be generally used for influencing a charge state of a sample. It is furthermore pointed out that only individual embodiments of the invention can be described in detail hereinafter. However, a person skilled in the art will understand that the features and modification options described in association with these embodiments can also be modified even further and/or can be combined with one another in other combinations or sub-combination without this leading away from the scope of the present invention. Moreover, individual features or sub-features can also be omitted provided that they are dispensable in respect of achieving the intended result. In order to avoid unnecessary repetition, reference is therefore made to the remarks and explanations in the preceding sections, which also retain their validity for the detailed description which now follows below.

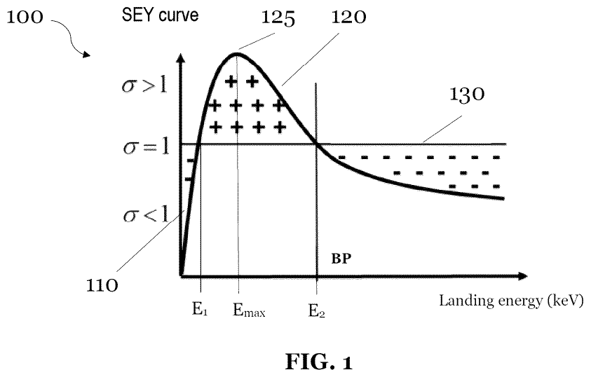

FIG. 1 schematically shows a diagram 100 showing a qualitative profile of the secondary electron yield (SEY) versus the electron landing energy on a sample, as already known from the prior art.

The secondary electron yield indicates the ratio of the number of electrons ejected from the sample as secondary electrons relative to the number of electrons incident on the sample (e.g., by virtue of a particle beam of electrons directed onto the sample), the particle beam at least partly causing the ejection of the secondary electrons.

In this context, an electron landing energy E_{L} is understood to mean the energy with which incident electrons are incident on the sample (e.g., in keV). The electron landing energy E_{L} may be defined by the acceleration voltage (e.g., in kV) of the electrons, decreased (or increased) by a possible opposing potential (e.g., in V or kV) of the sample, which may be caused by a charging of the sample, for example, and may have a repulsive effect (hence a decelerating effect, which may reduce the electron landing energy E_{L}) or an attractive effect (hence an accelerating effect, which may increase the electron landing energy E_{L}) on incident electrons.

The secondary electron yield may have a dependence on the landing energy E_{L}. The profile of the secondary electron yield may be able to be divided into three regions: A first region 110, comprising a landing energy range of 0 keV≤E_{L}≤E₁, a region 120, comprising a landing energy range of E₁<E_{L}≤E₂ (the region 120 comprising a landing energy Eₘₐₓ for which the secondary electron yield assumes a maximum value which is greater than 1), and a region 130, in which the landing energy E_{L} has a value E_{L} >E₂.

It should be noted that according to the textbook by R. F. Egerton:

“Physical Principles of Electron Microscopy,” Springer 2005, numerical values in the range of a few hundred electronvolts may be indicated for the lower energy threshold E₁ regarding landing energies of the electrons and numerical values in the range of approximately 1 keV to 10 keV for the upper energy threshold E₂.

In the region 110, associated with a landing energy E_{L}<E₁, the secondary electron yield is less than one, with the result that on average less than one electron is ejected from the sample per incident electron. This may have the effect that the sample becomes slightly negatively charged since, in this region 110, the number of electrons that are incident on the sample is more than the number of electrons that leave the sample.

If the landing energy E_{L} of the electrons is increased further (e.g., by increasing the acceleration voltage of the electrons), then as the landing energy E_{L} increases, more electrons are ejected from the sample and the SEY may assume a value of 1 for E₁ (depending on the mask material and the mask structure). For this value of the landing energy E₁, the sample exhibits no change in the charge state.

A further increase in the acceleration voltage of the electrons may result in a further increase in the landing energy E_{L} of the electrons, such that the secondary electron yield in the region 120 may assume a value greater than one. This may mean that the number of electrons leaving the sample is more than the number incident on the sample by virtue of a particle beam of electrons directed onto the sample. Since the number of electrons that may leave the sample is now more than the number incident thereon, this may result in a positive charging of the sample.

The positive charging of the sample in the region 120 may have the effect that an attractive potential for further electrons incident on the sample arises on the sample. Incident electrons may therefore experience an acceleration towards the sample as a result of the positive charging of the sample. The landing energy of the electrons in this regime is not solely determined by the acceleration voltage of the electrons, but rather by the sum of the acceleration voltage and the positive potential of the sample. The landing energy E_{L} of the electrons may therefore increase with increasing positive charging of the sample, with the acceleration voltage being unchanged. The secondary electron yield in this regime initially rises continuously with the landing energy E_{L}.

At a certain point, however, the positive charging of the sample is limited by the fact that increasingly fewer electrons may be ejected from the sample per incident electron. This may be explained by the fact that electrons of the particle beam may penetrate deeper into the sample with increasing landing energy and in the process may eject electrons from deeper layers of the sample. However, these latter electrons are often no longer able to leave the sample. This has the effect that the secondary electron yield assumes a maximum 125 for a landing energy Eₘₐₓ and afterwards falls again gradually (with increasing landing energy E_{L}).

In this case, the secondary electron yield may once again assume a value of one between the regions 120 and 130, for a landing energy E₂. The sample does not become charged in this region. This point is also referred to as the (material-specific) balance point BP.

A further increase in the landing energy E_{L} may have the effect that the secondary electron yield assumes a value of less than one. Consequently, the number of electrons incident on the sample is more than the number ejected by said sample as secondary electrons. This may result in a negative charging of the sample.

It should be noted, however, that the negative charging of the sample in the region 130 has a saturation behaviour for increasing landing energy E_{L} of the electrons. This may be explained by the ejection of electrons from deeper layers of the sample already described above, which electrons however can no longer reach the surface of the sample and therefore cannot leave the sample as secondary electrons.

As a result of the negative charging of the sample in the region 130, the sample may form a repulsive opposing potential for incident electrons, such that for an unchanged acceleration voltage of the electrons the effective landing energy E_{L} decreases and therefore tends in the direction of the balance point BP (landing energy E₂) with a secondary electron yield of 1. This may prevent a further dissipation of the negative charge of the sample.

In other words, if the acceleration voltage amounts to, e.g., 10 kV and the balance point BP is at, e.g., 2 keV, the sample potential may rise to a maximum value of −8 kV. If the mask potential has risen from 0 to −8 kV, then the electron landing energy corresponds to E_{L}=2 keV. Since this electron landing energy E_{L} corresponds exactly to the electron landing energy E_{L} associated with the balance point BP, the secondary electron yield is equal to 1 and no further charging or changing of the mask potential takes place.

Furthermore, it should be noted that the secondary electron yield of a sample may be dependent on the orientation of the sample relative to the incident charged particle beam (e.g., electron beam). In this regard, for example, as a result of the sample being arranged relative to the incident electron beam in a manner such that the electron beam does not exhibit normal incidence on a surface of the sample, an increase in the secondary electron yield may be observed, with operational parameters otherwise being the same. Additionally or alternatively, when the electron beam is directed onto a structure (in particular onto an edge of the structure) on the surface of the sample, an increase in the secondary electron yield may be observed. A structure of the sample may be, e.g., a layer that absorbs light transmitted by the sample.

In some exemplary cases, structures contained on the sample may also result in a shielding or a renewed binding of ejected secondary electrons to atoms of the sample material and/or structure material. This case may occur, e.g., if an electron beam is directed onto a depression (e.g., a groove, a hole, etc.) of the sample and/or of the structure.

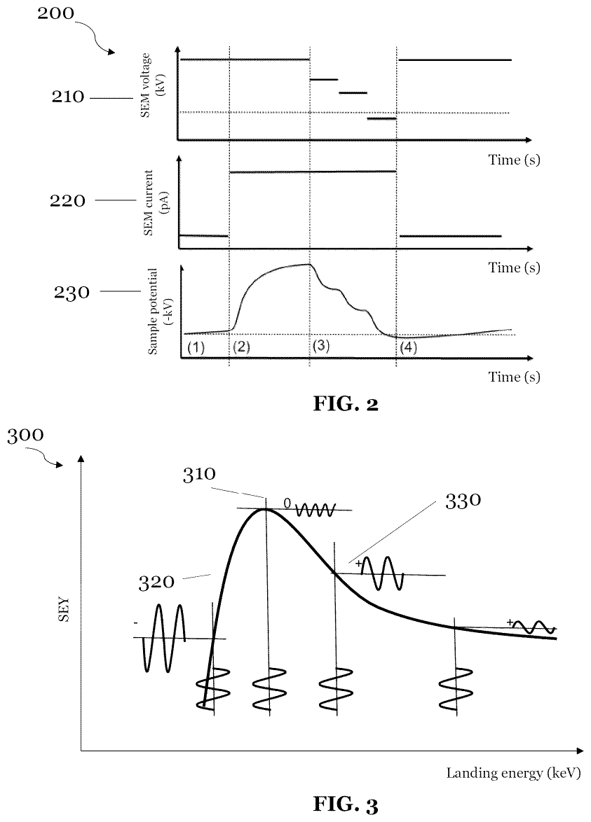

FIG. 2 schematically shows a comparison of diagrams 200 showing a time profile of characteristic operational parameters of a scanning electron microscope (SEM) and of a process parameter (mask potential) in accordance with one aspect of the present invention. The comparison of diagrams 200 depicts an exemplary application of an SEM imaging followed by an EDX analysis of the sample, as explained in greater detail below.

Diagram 210 shows by way of example the profile of an SEM acceleration voltage in the time profile.

Diagram 220 shows by way of example the profile of an SEM particle current in the time profile.

Diagram 230 shows by way of example the profile of a sample potential in the time profile.

It shall be assumed by way of example that firstly an SEM image recording takes place in a time interval (1). In this time interval, the SEM acceleration voltage (e.g., a first acceleration voltage as shown in diagram 210) is comparatively high, while the SEM particle current (diagram 220) is comparatively low. By virtue of the high SEM acceleration voltage chosen, the landing energy of the electrons is arranged in the region 130 (as described with reference to FIG. 1), and so this results in a slow negative charging of the sample in the time profile (as shown in diagram 230).

It shall furthermore be assumed that a foreign particle on the sample was able to be localized by the SEM imaging. In order to be able to determine the element composition of the detected foreign particle in more specific detail, an x-ray spectroscopy analysis (e.g., an EDX analysis) is carried out by way of example in the time interval (2). This x-ray spectroscopy analysis requires the generation of x-ray radiation, which may be generated by the electrons of the SEM. A high acceleration voltage of the electrons (diagram 210) and a high SEM particle current (diagram 220) are chosen for this purpose. The high SEM particle current chosen is associated with a large number of electrons, which, on account of the high SEM acceleration voltage, may be incident on the sample (region 130 as described with reference to FIG. 1) and may generate x-ray radiation there. However, this may also result in a rapid negative charging of the sample in the time profile, as illustrated in diagram 230 for the time interval (2).

It should be noted here that the sample potential forms a saturation behaviour in the time profile (as illustrated in diagram 230). This may be explained by the fact that in the time profile, the secondary electron yield approaches the balance point BP as described with reference to FIG. 1, since the charged sample forms an increasingly repulsive opposing potential for further electrons incident on the sample, whereby the effective landing energy of the electrons is reduced in the time profile. This also means that in the time profile just one electron is ejected from the sample per incident electron and the sample becomes charged in a retarded manner in the time profile.

However, the negative charging then prevailing on the sample would have the effect, during a subsequent SEM imaging, that the electrons required for this imaging would be repelled by the sample. This may have the effect that only inadequate SEM imaging is possible. It is therefore necessary to influence the charge state of the sample, e.g., to discharge the sample, before a subsequent SEM imaging.

Directly decreasing the SEM acceleration voltage (e.g., to a value close to zero) is not expedient, however, since, as a result of the negative charging of the sample, the electrons with low acceleration voltage would be repelled by the sample. In this case, the negatively charged sample would act as a mirror for incident electrons and an SEM imaging might likewise not be performed satisfactorily.

The applicant has recognized in this regard that, e.g., decreasing the SEM acceleration voltage step by step (e.g., with the SEM particle current unchanged relative to x-ray spectroscopy) may efficiently contribute to a discharge of the sample, as illustrated qualitatively in time segment (3).

What may be achieved by a reduction of the SEM acceleration voltage (e.g., to a second acceleration voltage) is that the secondary electron yield is increased. Preferably, the reduction contribution should in this case be chosen in such a way that it corresponds to a little less than the energy associated with the balance point BP (may be determined experimentally and/or gathered from the literature, for example). This means that the secondary electron yield undergoes deflection from the balance point BP towards the region 120 (as described with reference to FIG. 1), which is associated with a positive charging of the sample or a dissipation of a negative charging of the sample. This also means, in particular, that the secondary electron yield now assumes a value of greater than one. Consequently, now there will be more than one electron leaving the sample per incident electron, with the result that the charge of the sample decreases in the time profile. In some cases, provision may also be made for reducing the acceleration voltage in such a way that the landing energy of the electrons E_{L} after reduction corresponds to a value E₁<E_{L}<Eₘₐₓ. What may be achieved in this way is that the secondary electron yield may assume a value of greater than one for as long as possible (over time), whereby a particularly efficient discharge of the sample may be made possible.

The decrease in the charge on the sample results in a decrease in the sample potential in the time profile and thus also in the repulsive opposing potential opposite to the incident electrons, as illustrated, e.g., in diagram 230 for time interval (3).

This means that the landing energy of the electrons for the SEM acceleration voltage chosen increases again in the time profile. With reference to FIG. 1, this means, in particular, that the secondary electron yield drifts back again from the region 120 to the balance point BP and in the process decreases until finally, having arrived at the balance point BP, it again reaches a value of one.

Decreasing the acceleration voltage once again (e.g., to a third, fourth, ..., N-th acceleration voltage) enables the process described above to be performed repeatedly and the charging or the potential of the sample to be reduced further (step by step). Reducing the acceleration voltage may thus take place, e.g., in one step, in two steps, in three steps, in four steps, in five steps, in ten steps, in 15 steps or in any other number of steps.

As shown in time interval (4), an initially negative charging of the sample may be reduced in such a way that it reaches a value of 0 V and furthermore assumes a low positive charging. In this regime, it may be possible to perform an SEM image recording without the above-described disadvantageous effects caused by a charging of the sample.

For such an SEM image recording, the SEM acceleration voltage may be increased again to a comparatively high value (e.g. to the first acceleration voltage, as shown in diagram 210) and the SEM particle current may be reset (as shown in diagram 220) to a low value (e.g. to the same value that was chosen for the SEM image recording in time interval (1)).

During the SEM image recording carried out in time interval (4), a renewed slow negative charging of the sample may take place, as already described with reference to time interval (1). It should be noted that the method described above may be executed periodically in order thus always to enable optimized conditions for an SEM image recording and/or x-ray spectroscopy.

FIG. 3 shows a further advantageous aspect 300 of the present invention, wherein the secondary electron yield is kept constant in a range which may result in as rapid influencing as possible of a charge state (e.g., a discharge) of a sample.

FIG. 3 schematically shows the profile of the secondary electron yield versus the landing energy of the electrons as already described with reference to FIG. 1. It should be noted at this juncture that the explanations presented below are given in respect of electrons in order to simplify understanding of the invention, but may also be applied, mutatis mutandis, to other suitable particle types and are therefore not restricted to electrons.

As likewise described with reference to FIG. 1, the secondary electron yield assumes a maximum value 310 for a specific landing energy. At this maximum value, the secondary electron yield is greater than one, which may advantageously be used to drive on an efficient and rapid influencing of a charge state of the sample (in particular a discharge of the sample).

As has likewise already been described above, the secondary electron yield and the landing energy (or the acceleration voltage of the electrons) are dependent on one another. This means that a reduction of the acceleration voltage (e.g., an SEM acceleration voltage as described with reference to FIG. 2) may initially result in an increase in the secondary electron yield, although the secondary electron yield may decrease again in the time profile (e.g., as a result of the SEY drifting back to the balance point BP). It may therefore be regarded as desirable to keep the secondary electron yield substantially constant at a certain value. It may be particularly preferred to keep the secondary electron yield constant at its maximum value 310 since at this point, for an incident electron, the greatest number of electrons may be ejected from the sample, which may result in the discharge of the sample in the time profile.

This may be achieved, e.g., by implementing a (closed) feedback loop which involves using the secondary electron yield as at least one process parameter associated with a present charge state of the sample as input variable for the feedback loop and using the acceleration voltage of the electrons as an operational parameter (or control parameter) of the feedback loop. In this way, e.g., as the secondary electron yield decreases in the direction of the balance point BP (as described with reference to FIG. 1), the acceleration voltage of the electrons may be adapted in such a way that ultimately no change in the secondary electron yield occurs. In this way, the secondary electron yield may be kept substantially constant (apart from control variations caused by the feedback loop) at its maximum value 310. As time-efficient influencing as possible of a charge state of the sample (e.g., a discharging of the sample) may thus be supported.

Specifically, this may mean that, if the secondary electron yield drifts from its maximum value 310 in the direction of the balance point BP (as described, e.g., by the region 330), the acceleration voltage is reduced in order thus to return the secondary electron yield again in the direction of its maximum value 310.

Alternatively, it may be possible that the secondary electron yield drifts from its maximum value 310 in the direction of a secondary electron yield associated with a lower landing energy than the maximum value 310 (indicated by a region 320). In this case, the feedback loop would adapt the acceleration voltage of the electrons in such a way that said acceleration voltage is increased in order thus to bring the secondary electron yield back again to its maximum value 310.

In some cases, it may indeed be the case that the secondary electron yield is subject to statistical fluctuations (e.g., caused by noise and/or other interference signals present in an environment in which the analysis is carried out or in which the sample is processed). In some cases, this might have the effect that the noise associated with the secondary electron yield would be transferred into noise of the acceleration voltage by the feedback loop. This may result in an unwanted and unstable feedback loop.

It may therefore be regarded as advantageous to provide means for suppressing noise of the secondary electron yield as much as possible. The applicant has recognized in this context that, e.g., lock-in techniques may be used in order to provide a feedback loop which keeps the at least one process parameter (e.g., the secondary electron yield) substantially constant, e.g., maximizes it, in the time profile.

For this purpose, provision may be made for modulating the acceleration voltage (as already described above) and for demodulating the signal of the at least one process parameter (e.g., the secondary electron yield) (preferably with the modulation frequency of the acceleration voltage). It may then be the case here that the demodulated signal does not include information about an absolute value of the at least one process parameter, but rather is a measure of the gradient thereof as a function of the acceleration voltage (e.g., the gradient of the secondary electron yield). The amplitude of the demodulated signal may be greater, for example, if the modulation takes place around a point of the acceleration voltage at which the process parameter has a high gradient. In the example of the secondary electron yield, the amplitude may therefore be used as a measure of how far away the maximum thereof is. The phase may in turn indicate whether the landing energy is presently to the left or right of the maximum. The acceleration voltage may thus be correspondingly tracked to the demodulated signal by use of feedback. It is thus possible to attain a stable closed-loop control which may be used, e.g., to set the acceleration voltage in such a way that the secondary electron signal is maximized.

Specifically, on the basis of the demodulated signal of the at least one process parameter, it is possible to ascertain whether the secondary electron yield (e.g., in the case of a negative sign of the amplitude) currently assumes a value to the left of its maximum value 310 (i.e., in the region 320) or whether the secondary electron yield (e.g., in the case of a positive sign of the amplitude) currently assumes a value to the right of its maximum value 310 (i.e., in the region 330). By contrast, if the secondary electron yield assumes its maximum value 310, then the amplitude may have a value of (close to) zero.

In an alternative exemplary case, provision may also be made for the acceleration voltage not to be subjected to a targeted modulation. In such a case, no (intentional) modulation of the at least one process parameter takes place either.

In such a case, the at least one process parameter may be kept at a substantially constant value by provision being made of a feedback loop which uses the at least one process parameter as input parameter and, on the basis of the input parameter, determines a value for at least the acceleration voltage which has the effect that the at least one input parameter is kept substantially constant.

One advantage of this type of closed-loop control may be seen, e.g., in the simple implementation thereof. What may be regarded as disadvantageous, by contrast, is that this type of closed-loop control in some cases, when controlling the at least one process parameter to a value which is comparatively close to the maximum value of the at least one process parameter, may result in the closed-loop control undesirably jumping from a range which is greater than the maximum value of the at least one process parameter (e.g., region 330) towards a range which is less than the maximum value of the at least one process parameter (e.g., region 320). What may happen in this case is that the feedback loop cannot be maintained as closed (e.g., at least partly on the basis of a reversal of the sign of the gradient of the curve profile of the at least one process parameter vs. acceleration voltage). A closed-loop control of the at least one process parameter to the maximum value thereof may therefore be made more difficult.

Furthermore, it may happen, if a sample is discharged, that the waveform, e.g., of the secondary electron yield (as illustrated, e.g., in FIG. 1) changes in the course of the discharging process (e.g., the maximum value of the secondary electron yield may change, e.g., become smaller). This may make it more difficult to carry out closed-loop control of the secondary electron efficiency in accordance with the described method without modulation, since e.g. a present maximum value of the secondary electron yield may fall below a chosen control value of the secondary electron yield.

In each of the cases mentioned, the feedback loop may be based at least partly on a two-point closed-loop control, a proportional-integral-derivative (PID) closed-loop control or some other suitable closed-loop control.

The secondary electron yield may be determined, e.g., by means of detecting the secondary electrons (e.g., using an in-lens detector) and subsequently relating the detected number of secondary electrons to the number of electrons incident on the sample (e.g., derivable from a chosen particle current). It should be noted in this context, however, that the detection efficiency of the secondary electrons by use of an in-lens detector may be dependent on the acceleration voltage of the electrons. This may necessitate a corresponding adaptation of the secondary electron yield signal determined.

Alternatively, the secondary electron yield may also be determined using an independent chamber detector.

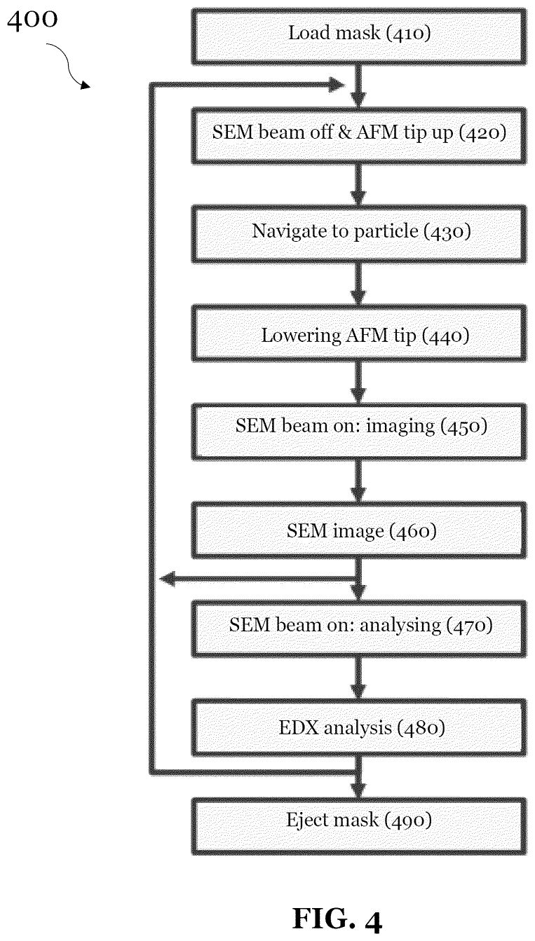

FIG. 4 shows an exemplary flow diagram of a method 400 for influencing a charge state of a sample in accordance with one aspect of the present invention. The method 400 is preferably executed in a device comprising both a scanning electron microscope (SEM) and a scanning probe microscope (e.g., AFM).

It shall be assumed hereinafter that the sample is provided as a mask (e.g., a lithographic mask), but is not restricted to masks.

The method 400 may begin, e.g., with loading 410 of the mask into a device that implements the method 400.

At this point in time 420, the SEM beam is preferably switched off and an AFM tip of the AFM is drawn back from the mask (i.e., the AFM tip is not in contact with the mask).

Afterwards, navigating 430 the AFM tip and the SEM beam to a particle on the sample (e.g., a foreign particle) may take place, which particle, e.g., is intended to be analyzed by the SEM beam and/or is intended to be processed (e.g., removed) by the AFM tip.

Once the AFM tip has arrived at the location of the particle, the AFM tip may be lowered 440 towards a surface of the mask. Preferably, the AFM tip may produce an electrically conductive connection between the sample and the AFM tip in this way. In this case, the AFM tip may be provided in such a way that it has a sufficient conductivity to prevent and/or dissipate a charging of the mask. The AFM tip may be connected to an earth potential, in particular. By way of a closed-loop control, the force between the AFM tip and the mask may be kept constant (and/or be kept below a maximum force which might result in damage to the mask and/or the AFM tip) in order to avoid damage to the AFM tip and/or the mask owing to an (electrically conductive) contacting.

Producing the electrically conductive connection may be followed by configuring 450 the SEM beam so that the latter might perform an imaging.

Recording 460 an SEM image may subsequently take place. In accordance with one preferred embodiment of the invention, the SEM beam may be switched on only if an electrically conductive connection between the AFM tip and the mask is present at the same time. In some cases, provision may be made for raising the AFM tip to result directly in switching off (referred to as: blanking) of the SEM beam. This may increase the reliability and the speed of the method 400.

The recording of the image may be taken as a basis for deciding whether x-ray spectroscopy (an analysis) of that region of the mask which is captured by the SEM image is required or whether possibly a different region of the mask ought to be analyzed. If it is decided that a different region of the mask ought to be analyzed, then steps 420-460, as described above, may be repeated on a different region of the mask. It should be taken into consideration here that if a different region of the mask ought to be analyzed, firstly the AFM tip must be drawn back from the mask by a few micrometres in order to prevent damage to the AFM tip and/or the mask. In principle, lowering and/or raising the AFM tip requires only a time expenditure of a few seconds and thus has only minimal influence on the throughput of a device that implements the method 400.

By contrast, if it is decided that that region of the mask which is captured by the SEM image ought to be analyzed more closely, then configuring 470 the SEM beam may follow, thereby enabling provision of the SEM beam with an operational parameter for analyzing the mask further. These operational parameters may comprise, e.g., an increase in the particle current and/or an increase in the acceleration voltage, such that the SEM beam, when incident on the sample, may generate x-ray radiation in the mask.

X-ray spectroscopy (e.g., an EDX analysis) 480 may subsequently be carried out.

A decision may subsequently be taken as to whether a different region of the mask ought to be analyzed in accordance with steps 420-480 described above or whether ejecting 490 the mask ought to take place. In this case, provision may be made for ejecting 490 the mask to be preceded by switching off the SEM beam and drawing back the AFM tip from the surface of the mask.

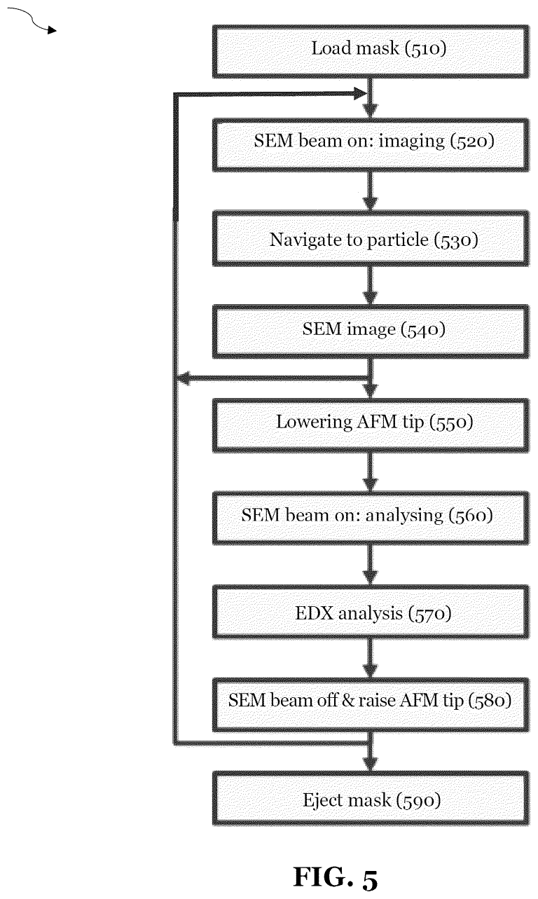

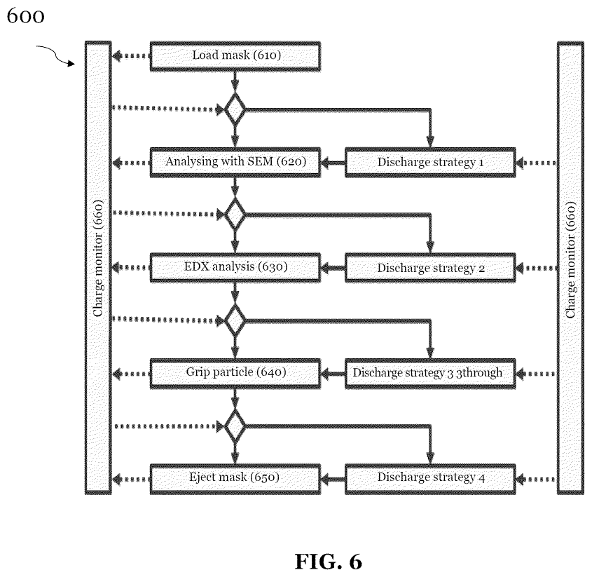

FIG. 5 shows an exemplary flow diagram of a method 500 for influencing a charge state of a sample in accordance with a further aspect of the present invention. The method 500 is preferably executed in a device comprising both a scanning electron microscope (SEM) and a scanning probe microscope (AFM).

The method 500 may begin with loading 510 of the sample (e.g., a mask).

Configuring 520 the SEM beam may subsequently take place, such that said SEM beam is configured with at least one operational parameter which may be used for an imaging (analogously to step 470 as described above). The SEM beam may already be switched on at this point in time or still be switched off.

Provision may subsequently be made for navigating 530 to a particle to be examined (e.g., to a foreign particle). The navigating may comprise aligning the SEM beam with a region of the sample (but without switching on the SEM beam itself) and/or moving an AFM tip towards the relevant region. In parallel with this, the sample does not become charged or at least becomes charged slowly (depending on the at least one operational parameter chosen).

Recording 540 an SEM image may subsequently take place. At least partly on the basis of the recorded SEM image, a decision may be taken as to whether a different region of the mask ought to be examined or whether the particle encompassed by the SEM image ought to be analyzed more closely.

If it is decided that a different region of the mask ought to be analyzed, then steps 520-540 may be performed once again on a different region of the mask, as described above.

By contrast, if it is decided that further analyzing of the particle is required, then lowering 550 of the AFM tip in the region of the SEM image may take place. The lowering of the AFM tip may preferably take place in such a way that an electrically conductive connection between the AFM tip and the mask is produced (e.g., by way of contacting). In this case, provision may be made for lowering 550 of the AFM tip to take place only if, for the SEM beam, at least one operational parameter is used which might be expected to result in a charging of the mask (e.g., in cases in which x-ray spectroscopy is required). In some cases, lowering of the AFM tip may be dispensed with if operational parameters for the SEM beam are used which allow a secondary electron yield of one to be expected (i.e., substantially no charging of the mask should be expected). In this way, in some cases, step 550 may be skipped and a throughput of a device that implements the method 500 may thus advantageously be increased.

Configuring 560 the SEM beam may subsequently take place, such that said SEM beam may be implemented for analyzing that region of the mask (e.g., encompassing the particle) which is captured by the SEM image (analogously to step 470 as described above).

Performing 570 x-ray spectroscopy (e.g., an EDX analysis) may subsequently take place at least partly on the basis of the configured SEM beam.

Conclusion of the x-ray spectroscopy may be followed by switching off 580 the SEM beam and raising the AFM tip from the mask.

A decision may subsequently be taken as to whether a further region of the mask ought to be analyzed in accordance with steps 530-580 or whether ejecting 590 the mask from the device that implements the method ought to take place.

In some cases, the SEM beam may be used once again for recording an SEM image. In these cases, the SEM beam may be operated with the parameters configured in step 520. In these cases (i.e., if said SEM beam is not intended to be used for performing x-ray spectroscopy in accordance with step 570), producing once again an electrically conductive connection between the AFM tip and the mask may be dispensed with.

FIG. 6 shows an exemplary flow diagram of a method 600 for influencing a charge state of a sample in accordance with a further aspect of the present invention. The method 600 is preferably executed in a device comprising both a scanning electron microscope (SEM) and a scanning probe microscope (AFM).

The method 600 may comprise loading 610 of a mask. If the mask is successfully loaded, then the loading of the mask may be communicated to a charge monitor 660.

SEM-based analyzing 620 of the mask may subsequently take place to establish whether, e.g., a particle (e.g., a foreign particle) is depicted in the SEM recording. Before the actual analyzing 620 is performed, firstly the charge monitor 660 may be queried with regard to a present charge state of the mask. If the present charge state of the mask reported by the charge monitor 660 falls below a (predefined) threshold value, then the analyzing 620 of the mask may be begun immediately. This may be communicated to the charge monitor 660.

By contrast, if it is ascertained that the present charge state of the mask reported by the charge monitor 660 exceeds a (predefined) threshold value, then firstly a discharge strategy 1 is executed. The discharge strategy 1 once again requests the present charge state of the mask from the charge monitor 660. On the basis of the reported charge state, a suitable discharge strategy 1 may be selected which may efficiently enable a rapid discharge of the mask, with the result that the analyzing 620 by use of SEM may be begun promptly, without disadvantageous effects for the SEM imaging and/or without the possible occurrence of unwanted discharges from the mask towards an AFM tip.

After discharge strategy 1 has been successfully executed, the analyzing 620 may be begun. If the analyzing 620 is begun, this may be communicated to the charge monitor 660.

If a decision is taken following the analyzing 620 that x-ray spectroscopy (e.g., an EDX analysis) ought to be performed, then firstly the present charge state of the mask may once again be requested from the charge monitor 660. If the present charge state of the mask thus obtained falls below a (predefined) threshold value (up to which x-ray spectroscopy may be carried out successfully), then analyzing 630 on the basis of x-ray spectroscopy may be begun immediately. This may be communicated to the charge monitor 660.

By contrast, if it is ascertained that the present charge state of the mask reported by the charge monitor 660 exceeds a (predefined) threshold value, then firstly a discharge strategy 2 may be carried out. Discharge strategy 2 may likewise request the present charge state of the mask from the charge monitor 660. Discharge strategy 2 may be chosen in such a way that a discharge of the mask that is as rapid as possible may be made possible and successfully carrying out the analysis 630 by use of x-ray spectroscopy may be ensured on the basis of the resulting discharge state. In this case, too, the carrying out of the analysis 630 may be communicated to the charge monitor 660.

If it is ascertained, e.g., at least partly on the basis of the analysis 630 that a particle (e.g., a foreign particle) on the mask ought to be removed, then firstly the present charge state of the mask may once again be requested from the charge monitor 660. If the present charge state of the mask thus reported falls below a (predefined) threshold value, then the gripping or removing 640 of the particle may be begun immediately. This may be communicated to the charge monitor 660. By contrast, if it is ascertained that the reported present charge state of the mask exceeds a (predefined) threshold value, then firstly a discharge strategy 3 may be carried out. Discharge strategy 3 may request the present charge state of the mask from the charge monitor 660. A suitable discharge strategy 3 may be selected on the basis of the present charge state of the sample thus reported and on the basis of the charging of the mask that can be afforded maximum tolerance for removing 640 the particle. After this has been carried out successfully, the removing 640 of the particle may be begun. This may be communicated to the charge monitor 660.

Ejecting 650 the mask may subsequently take place. Before this step is performed, however, a present charge state of the mask may once again be requested from the charge monitor 660. If the reported present charge state of the mask falls below a (predefined) threshold value, then the ejecting 650 of the mask may be begun immediately. This may be communicated to the charge monitor 660. By contrast, if the reported present charge state of the mask exceeds the (predefined) threshold value, then firstly discharge strategy 4 may be executed. Discharge strategy 4 may request the present charge state of the mask from the charge monitor 660. On the basis of the present charge state of the mask thus obtained, a suitable discharge strategy 4 may be selected, such that rapid discharging of the mask and attaining of a charging of the mask that can be afforded maximum tolerance for the ejecting 650 may be achieved.

In this case, discharge strategies 1-4 may be based on an identical discharge strategy or differ from one another at least with regard to two discharge strategies. Preferably, the discharge strategy is chosen here in such a way that its influence on a throughput of a device that implements the method 600 is minimized.

For each of steps 610, 620, 630, 640 and 650 mentioned above, it is possible to determine in each case an identical charging threshold value which can be afforded maximum tolerance and which is taken as a basis for deciding about a discharge strategy 1-4 possibly needed. Alternatively, it is possible for at least two mutually different threshold values to be determined for each of steps 610, 620, 630, 640 and 650.

In this case, the charge monitor 660 may be configured in such a way that it (continuously) monitors a present charge state of the mask.

It should furthermore be noted that each instance of communicating successful performance of one of the method steps mentioned above may also comprise communicating the present charge state of the mask (e.g., after the respective method step has ended).

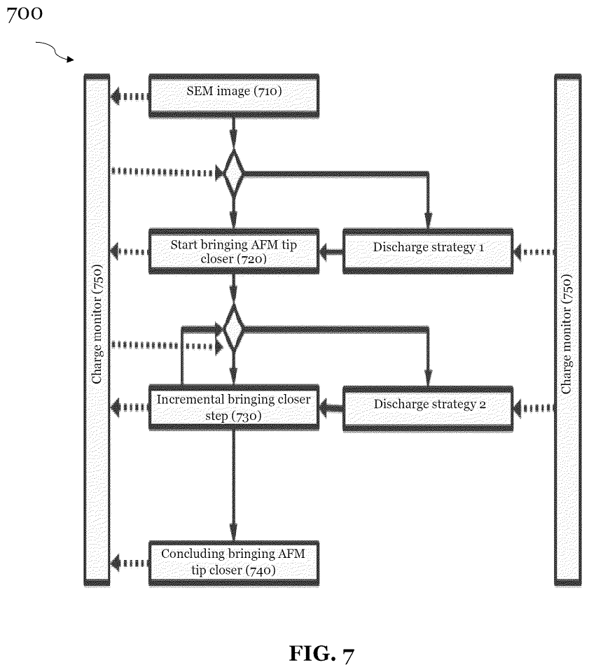

FIG. 7 shows an exemplary method 700 for monitoring a charge state of a sample (such as, e.g., a mask) by way of a charge monitor in accordance with one aspect of the present invention.

The monitoring may begin by way of example with the recording 710 of an SEM image.

At least partly on the basis of the recorded SEM image, bringing an AFM tip closer towards a sample may be initiated in order, e.g., to pick up a particle (e.g., a foreign particle) on the sample and, if appropriate, to remove it from the sample.

This may necessitate bringing an AFM tip closer to the sample, by means of which AFM tip the particle may be removed. Before bringing 720 the AFM tip closer towards the sample is initiated, firstly a present charge state of the sample may be requested from a charge monitor 750. If the present charge state falls below a (predefined) threshold value, then bringing 720 the AFM tip closer towards the sample may be started immediately. This may be communicated to the charge monitor 750.

If the present charge state exceeds a (predefined) threshold value, then a discharge strategy 1may be initiated. Discharge strategy 1 may request the present charge state of the sample from the charge monitor 750. On the basis of the present charge state of the sample and a charge state which can be afforded maximum tolerance for the bringing closer 720, a suitable discharge strategy 1 may be selected (e.g., a plasma discharge) and carried out. Bringing 720 the AFM tip closer may subsequently be started. This process may be communicated to the charge monitor 750.

The start of the bringing closer 720 may be followed by incremental, step-by-step bringing closer 730. Before incremental bringing closer takes place, once again the charge monitor 750 may be queried with regard to a present charge state of the sample. If said charge state falls below a (predefined) threshold value, then the incremental bringing closer 730 may be begun immediately. This may be communicated to the charge monitor 750. By contrast, if the reported present charge state of the sample exceeds a (predefined) threshold value, then a discharge strategy 2 may be executed. Discharge strategy 2 may request the present charge state of the sample from the charge monitor 750. At least partly on the basis of the requested present charge state of the sample and a charge state which can be afforded maximum tolerance for the incremental bringing closer step 730, a suitable discharge strategy 2 may be determined and executed. The incremental bringing closer step 730 may subsequently be performed. This may once again be communicated to the charge monitor 750.

The described sequence of the incremental bringing closer 730 may be executed repeatedly (e.g., in a loop). In particular, in each of the incremental bringing closer steps the AFM tip may function as a probe which may detect an interaction between the AFM tip and a possibly charged sample. The interaction may comprise, e.g., a repulsion of the AFM tip away from the sample or an attraction of the AFM tip towards the sample. Consequently, an analysis of a present charge state of the sample may take place with each step of bringing the AFM tip closer towards the sample. The smaller the chosen distance between the AFM tip and the sample, the better the actual charge state of the sample may be resolved.

By virtue of the AFM tip being brought closer towards the sample step by step, in particular an unwanted flashover from the possibly charged sample towards the AFM tip, which may result in damage to the AFM tip and/or to the sample, may be efficiently prevented and detailed information about a present charge state of the sample may be obtained. If it is ascertained, e.g., that the sample already has an increased charging, then firstly a discharge of the sample may be initiated before the AFM tip is guided further to the sample in a subsequent incremental bringing closer step.

Finally, concluding 740 the bringing of the AFM tip closer to the sample may take place. Concluding the bringing closer may comprise producing an electrically conductive connection between the AFM tip and the sample (e.g., by way of contacting), as described herein.

It should furthermore be noted that each instance of communicating successful performance of one of the method steps mentioned above may also comprise communicating the present charge state of the sample (e.g., after the respective method step has ended).

In some cases, the incremental, step-by-step bringing closer 730 may be at least partly replaced by continuous bringing of the AFM tip closer to the sample. It may be possible for information regarding a present charge state of the sample to be acquired already during the bringing of the AFM tip closer to the sample. In some cases, provision may be made for performing influencing of the charge state of the sample (e.g., discharging) in parallel with the bringing closer. Preferably, e.g., during the bringing of the AFM tip closer towards the sample, an SEM beam with an acceleration voltage of, e.g., 1 kV may be directed onto the sample and in the process, e.g., contribute to a discharge of the sample. Producing an electrically conductive connection between the AFM tip and the sample may be followed by configuring the SEM beam for recording an SEM image.

In some cases, the bringing closer may be based on a combination of step-by-step and continuous bringing closer. In this regard, it may, e.g., be possible for the AFM tip firstly to be continuously brought closer to a surface of the sample to approximately 10 μm away by use of a piezo. If the AFM tip has not yet touched the surface of the sample, then the AFM tip may be pulled back again by 10 μm. Afterwards, the AFM tip may be brought closer to approximately 5-8 μm away from the surface of the sample by use of a coarse drive, with the surface not being touched. Afterwards, the tip may once again be brought closer to the surface of the sample by use of a piezo, proceeding from the position of the AFM tip after bringing closer by use of the coarse drive. This alternation of continuous and step-by-step bringing closer may take place until the AFM tip makes contact with the surface of the sample.

The discharge strategies as described with reference to FIG. 7 may at least partly correspond to the discharge strategies 1-4 as described with reference to FIG. 6. In particular, a discharge strategy may also be implemented at least partly on the basis of a suitable choice of the SEM parameters.

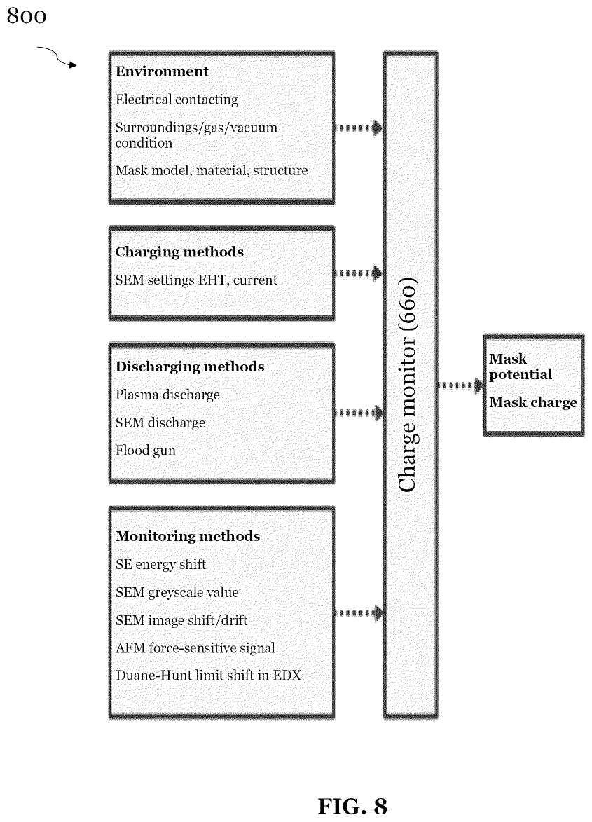

FIG. 8 shows an exemplary illustration of a model 800 for monitoring a charge state of a sample in accordance with one aspect of the present invention. In addition or as an alternative to monitoring a charge state of the sample on the basis of at least one measured process parameter (described herein), it is possible to provide monitoring at least partly on the basis of a model of the charging process. The model may be based on a known characteristic of the influence of the at least one process parameter on a charge state of the sample.

In order to determine a charge state of the sample, e.g., at least one process parameter which is based at least partly on an environment of the sample may be chosen. This at least one process parameter may comprise, e.g., information associated with the manner of the electrical contacting (insulated regions possibly present on the sample, earthings, etc.). Additionally or alternatively, it is also possible for the at least one process parameter to be associated with surroundings of the sample (e.g., temperature, air humidity, etc.), a gas atmosphere (in which the sample is situated), vacuum conditions to which the sample is subjected. In some cases, the at least one process parameter may be based at least partly on properties of the sample (e.g., of a mask). In this regard, the at least one process parameter may be based, e.g., on a material mix of the sample and/or a structure of the sample (e.g., the number of edges present on the sample).

Additionally or alternatively, it is possible for the model to be based at least partly on at least one process parameter associated with a charging method for the sample. This may comprise, e.g., SEM settings (such as, e.g., an SEM acceleration voltage (referred to as: electron high tension (EHT)) and/or an SEM particle current.

Additionally or alternatively, it is possible for the model to be based at least partly on at least one parameter associated with a discharging method for the sample. In this regard, the at least one process parameter may be associated with a plasma discharge, an SEM discharge (e.g., particle current) and/or operation of a flood gun.

Additionally or alternatively, it is possible for the at least one process parameter to be associated with at least one monitoring method. This may include, e.g., an energy shift of secondary electrons, an SEM greyscale value, an SEM image shift and/or an SEM image drift, an AFM force-sensitive signal (e.g., an attractive force between the AFM tip and the sample) and/or an energy shift of the cut-off edge of a bremsspectrum according to the Duane-Hunt limit in EDX applications. The latter may, e.g., make it possible for a present charge state of the sample to be able to be deduced by determining the energy of the cut-off edge of a bremsspectrum. This may be made possible by virtue of the energy value of the cut-off edge of the bremsspectrum in the absence of a charging of the sample being equal to the acceleration voltage of the incident electrons. Any deviation from this theoretical correlation may be explained, e.g., by a charging of the sample. By way of example, if a positive charging of the sample is present, incident electrons may be accelerated towards the sample. This may have the effect that the effective landing energy of the electrons is higher than the acceleration voltage thereof. This may result in the energy of the cut-off edge being shifted towards a higher energy than would be expected owing to the acceleration energy of the electrons. By contrast, if the sample is negatively charged, then incident electrons may be decelerated by the opposing potential of the sample, which may result in a correspondingly reduced landing energy of the electrons on the sample. This in turn may have the effect that the energy of the cut-off edge of the bremsspectrum is shifted towards lower energies than would be theoretically expected on the basis of the acceleration voltage of the electrons.

The respective at least one process parameter may be fed to a charge monitor which may (continuously) monitor a charge state of the sample on the basis of the information made available. From this the charge monitor may provide information regarding a present sample potential (e.g., mask potential) and/or a present sample charge (e.g., mask charge).

In the following, further examples are provided which facilitate the understanding of the present invention:
1. Method for influencing a charge state of a sample, comprising:
   directing a charged particle beam onto the sample for the purpose of analyzing and/or processing the sample, wherein the particles of the particle beam are accelerated onto the sample by a first acceleration voltage and result in charging of the sample;
      directing the charged particle beam onto the sample for the purpose of influencing the charging of the sample, wherein the particles of the particle beam are accelerated onto the sample by a second, changed acceleration voltage amounting to at least 15% of the first acceleration voltage.
2. Method according to Example 1, wherein the second, changed acceleration voltage is less than the acceleration voltage.
3. Method according to either of Examples 1 and 2, wherein the analyzing comprises recording x-ray beams generated in the sample by the particle beam.
4. Method according to any of the preceding examples, wherein the first acceleration voltage amounts to at least 1 kV, more preferably at least 3 kV and most preferably at least 4 kV.
5. Method according to any of the preceding examples, wherein the second acceleration voltage amounts to at least 30%, preferably at least 40%, particularly preferably at least 50% and most preferably at least 60% of the first acceleration voltage for analyzing.
6. Method according to any of the preceding examples, wherein the particle beam for the analyzing amounts to a particle current of at least 5 pA, preferably at least 1 nA and most preferably at least 150 nA.
7. Method according to any of the preceding examples, wherein the particle current during the analyzing and/or processing of the sample is substantially equal to the particle current during the influencing of the charging of the sample.
8. Method according to any of the preceding examples, comprising:
   directing the charged particle beam onto the sample N times for the purpose of influencing the charging of the sample, wherein the particles are accelerated onto the sample by a respectively N-th acceleration voltage, wherein N is greater than or equal to two.
9. Method according to Example 8, wherein the N-th acceleration voltage amounts to at least 30%, preferably at least 40%, particularly preferably at least 50%, very particularly preferably at least 60% and most preferably 70% of the (N−1)-th acceleration voltage.
10. Method according to either of Examples 8 and 9, wherein the N-th acceleration voltage is at least 250 V less than the (N−1)-th acceleration voltage and/or wherein the N-th acceleration voltage is at most 4 kV less than the (N−1)-th acceleration voltage.
11. Method according to any of Examples 8-10, wherein the directing N times takes place successively and reducing the acceleration voltage at least twice is carried out in the process.
12. Method according to Example 11, wherein the reducing at least twice takes place by the same absolute value in each case.
13. Method according to Example 11, wherein the reducing at least twice takes place in such a way that the reduction absolute values follow a logarithmic profile.
14. Method according to any of the preceding examples, wherein the particle beam is directed onto the sample without interruption between at least two acceleration voltages.
15. Method according to any of the preceding examples, wherein the influencing comprises reducing the charging of the sample.
16. Method according to any of the preceding examples, furthermore comprising:
   detecting at least one process parameter associated with a present charge state of the sample.
17. Method according to Example 16, wherein the second acceleration voltage is at least partly based on the at least one process parameter.
18. Method according to either of Examples 16 and 17, wherein the detecting furthermore comprises:
   modulating the acceleration voltage; and
   demodulating the at least one process parameter.
19. Method according to any of Examples 16-18, furthermore comprising:
   directing the particle beam onto the sample by use of an acceleration voltage which is at least partly based on a closed feedback loop including the at least one process parameter as input variable.
20. Method according to Example 18 or 19, wherein the at least one process parameter is kept substantially constant in a time profile.
21. Method according to any of Examples 16-20, wherein the at least one process parameter is associated with a secondary electron yield, SEY.
22. Method according to any of the preceding examples, wherein recording a scanning electron microscope, SEM, image occurs upstream and/or downstream of the method.
23. Method according to any of the preceding examples, furthermore comprising:
   providing an electrically conductive element;
   at least partly directing the charged particle beam onto the electrically conductive element in order to eject secondary particles from the electrically conductive element.
24. Method (400; 500; 800) for influencing a charge state of a sample, comprising:
   providing a scanning probe microscope, SPM, tip (420; 550; 820);
      producing (440; 550) an electrically conductive connection between the sample and the SPM tip for the purpose of influencing the charge state.
25. Method According to Example 24, Furthermore Comprising:
   directing (460, 470; 540, 560) a particle beam onto the sample for the purpose of analyzing and/or processing the sample; and
   wherein producing (440; 550) the electrically conductive connection is at least partly based on a measured and/or expected charge state of the sample.
26. Method according to Example 24 or 25, wherein the method takes place in a combined scanning probe microscope-scanning electron microscope device.
27. Method according to Example 26, wherein producing the electrically conductive connection takes place by bringing (440; 550; 830, 840) the SPM tip closer to a surface of the sample.
28. Method according to Example 27, wherein the bringing closer takes place at least partly on the basis of detecting at least one process parameter.
29. Method for monitoring a charge state of a sample, comprising:
   detecting a process parameter associated with the charge state of the sample, and wherein the process parameter was recorded by a scanning electron microscope, SEM, a scanning probe microscope, SPM, and/or an x-ray detector;
   determining the charge state of the sample at least partly on the basis of the process parameter.
30. Method according to Example 29, wherein the determining takes place at least partly by way of a previously known relationship of the process parameter and the charge state of the sample.
31. Method according to either of Examples 29 and 30, wherein the determining is at least partly based on detecting an interaction between a tip of the SPM and the sample.
32. Method according to any of Examples 29-31, furthermore comprising: initiating a method for influencing the charge state of the sample if a predetermined charge threshold value of the sample is exceeded.
33. Computer program comprising code for executing a method according to any of Examples 1-32.
34. Device for influencing a charge state of a sample, comprising:
   an electrically conductive element and/or a particle beam of a scanning electron microscope, SEM, and/or an x-ray detector;
   means for automatically executing the method according to any of Examples 1-30.
35. Device according to Example 34, furthermore comprising:
   means for controlling a distance between the electrically conductive element and the sample and/or an acceleration voltage of the particle beam.
36. Device according to either of Examples 34 and 35, further comprising:
means for executing the computer program according to Example 33.

What is claimed is:

1. A method for influencing a charge state of a sample, comprising:
providing a scanning probe microscope, SPM, tip;
producing an electrically conductive connection between the sample and the SPM tip for the purpose of influencing the charge state; and
directing a particle beam onto the sample for the purpose of analyzing and/or processing the sample;
wherein producing the electrically conductive connection is at least partly based on a measured and/or expected charge state of the sample.

2. A method for influencing a charge state of a sample, comprising:
providing a scanning probe microscope, SPM, tip;
producing an electrically conductive connection between the sample and the SPM tip for the purpose of influencing the charge state;
wherein the method takes place in a combined scanning probe microscope-scanning electron microscope device.

3. The method of claim 1, wherein the method takes place in a combined scanning probe microscope-scanning electron microscope device.

4. The method of claim 3, wherein producing the electrically conductive connection takes place by bringing the SPM tip closer to a surface of the sample.

5. The method of claim 4, wherein the bringing closer takes place at least partly on the basis of detecting at least one process parameter.

6. A method for monitoring a charge state of a sample, comprising:
detecting a process parameter associated with the charge state of the sample, and wherein the process parameter was recorded by a scanning electron microscope, SEM, a scanning probe microscope, SPM, and/or an x-ray detector;
determining the charge state of the sample at least partly on the basis of the process parameter; and
initiating a method for influencing the charge state of the sample if a predetermined charge threshold value of the sample is exceeded.

7. The method of claim 6, wherein the determining takes place at least partly by way of a previously known relationship of the process parameter and the charge state of the sample.

8. The method of claim 6, wherein the determining is at least partly based on detecting an interaction between a tip of the SPM and the sample.

9. A method for influencing a charge state of a sample, comprising:
directing a charged particle beam onto the sample for the purpose of analyzing and/or processing the sample, wherein the particles of the particle beam are accelerated onto the sample by a first acceleration voltage and result in charging of the sample; and
directing the charged particle beam onto the sample N times for the purpose of influencing the charging of the sample, wherein the particles of the particle beam are accelerated onto the sample by a respective second to (N+1)-th acceleration voltage, wherein:
N is greater than or equal to two; and
the second acceleration voltage amounts to at least 15% of the first acceleration voltage;
wherein the second acceleration voltage differs from the first acceleration voltage.

10. The method of claim 9, wherein the second acceleration voltage is less than the first acceleration voltage.

11. The method of claim 9, wherein the analyzing comprises recording x-ray beams generated in the sample by the particle beam.

12. The method of claim 1, wherein the first acceleration voltage amounts to at least 1 kV, more preferably at least 3 kV and most preferably at least 4 kV.

13. The method of claim 1, wherein the second acceleration voltage amounts to at least 30%, preferably at least 40%, particularly preferably at least 50% and most preferably at least 60% of the first acceleration voltage for analyzing.

14. The method of claim 1, wherein the particle beam for the analyzing amounts to a particle current of at least 5 pA, preferably at least 1 nA and most preferably at least 150 nA.

15. The method of claim 1, wherein the particle current during the analyzing and/or processing of the sample is substantially equal to the particle current during the influencing of the charging of the sample.

16. The method of claim 1, wherein the N-th acceleration voltage amounts to at least 30%, preferably at least 40%, particularly preferably at least 50%, very particularly preferably at least 60% and most preferably 70% of the (N−1)-th acceleration voltage.

17. The method of claim 1, wherein the N-th acceleration voltage is at least 250 V less than the (N−1)-th acceleration voltage and/or wherein the N-th acceleration voltage is at most 4 kV less than the (N−1)-th acceleration voltage.

18. The method of claim 1, wherein the directing N times takes place successively and reducing the respective acceleration voltage at least twice is carried out in the process.

19. The method of claim 18, wherein the reducing at least twice takes place by the same absolute value in each case.

20. The method of claim 18, wherein the reducing at least twice takes place in such a way that the reduction absolute values follow a logarithmic profile.

21. The method of claim 1, wherein the particle beam is directed onto the sample without interruption between at least two acceleration voltages.

22. The method of claim 1, wherein the influencing comprises reducing the charging of the sample.

23. The method of claim 1, furthermore comprising:
detecting at least one process parameter associated with a present charge state of the sample.

24. The method of claim 23, wherein the second acceleration voltage is at least partly based on the at least one process parameter.

25. The method of claim 23, wherein the detecting furthermore comprises:
modulating the acceleration voltage; and
demodulating the at least one process parameter.

26. The method of claim 23, furthermore comprising:
directing the particle beam onto the sample by use of an acceleration voltage which is at least partly based on a closed feedback loop including the at least one process parameter as input variable.

27. The method of claim 25, wherein the at least one process parameter is kept substantially constant in a time profile.

28. The method of claim 23, wherein the at least one process parameter is associated with a secondary electron yield, SEY.

29. The method of claim 1, wherein recording a scanning electron microscope, SEM, image occurs upstream and/or downstream of the method.

30. The method of claim 1, furthermore comprising:
providing an electrically conductive element;
at least partly directing the charged particle beam onto the electrically conductive element in order to eject secondary particles from the electrically conductive element.

31. A computer program comprising code for executing a method according to claim 1.

32. A device for influencing a charge state of a sample, comprising:
an electrically conductive element and/or a particle beam of a scanning electron microscope, SEM, and/or an x-ray detector;
means for automatically executing the method of claim 1.

33. The device of claim 32, furthermore comprising:
means for controlling a distance between the electrically conductive element and the sample and/or an acceleration voltage of the particle beam.

34. The device of claim 32, further comprising:
means for executing the computer program according to claim 31.
